(19) United States
(12) Patent Application Publication
(10) Pub. No.: US 2026/0089952 A1
(43) Pub. Date: Mar. 26, 2026

(54) NON-VOLATILE MEMORY DEVICE, METHOD OF MANUFACTURING THE SAME, AND MEMORY SYSTEM INCLUDING THE SAME

(71) Applicant: Samsung Electronics Co., Ltd., Suwon-si (KR)

(72) Inventors: Jaeryong SIM, Suwon-si (KR); Kohji KANAMORI, Suwon-si (KR); Sejie TAKAKI, Suwon-si (KR); Jeehoon HAN, Suwon-si (KR)

(73) Assignee: Samsung Electronics Co., Ltd., Suwon-si (KR)

(21) Appl. No.: 19/319,946

(22) Filed: Sep. 5, 2025

(30) Foreign Application Priority Data
Sep. 26, 2024 (KR) 10-2024-0131072

(51) Int. Cl. H10B 43/27; G11C 5/06; G11C 16/04; H01L 23/00; H01L 25/18; H10B 41/27; H10B 41/35; H10B 41/41; H10B 43/35; H10B 43/40; H10B 80/00; H10D 80/30

(52) U.S. Cl. CPC H10B 43/27; G11C 5/063; G11C 16/0483; H10B 41/27; H10B 41/35; H10B 41/41; H10B 43/35; H10B 43/40; H10B 80/00; H10D 80/30; H10W 90/00; H10W 90/20; H10W 90/732; H10W 90/734; H10W 90/792

(57) ABSTRACT

A non-volatile memory device including a peripheral circuit structure and a cell array structure may be provided. The cell array structure may include a common source line layer, a bit line, a bit line wiring insulation layer, a cell stack provided between the common source line layer and the bit line and including a plurality of gate electrodes and a plurality of interlayer insulation layers, and a plurality of channel structures extending through the cell stack into the bit line wiring insulation layer. Each of the plurality of channel structures includes a channel layer electrically connected to the common source line layer, a bit line pad electrically connecting the channel layer to the bit line and being adjacent to one end of the channel layer facing the bit line, and a gate insulation layer covering the channel layer and the bit line pad.

### CROSS-REFERENCE TO RELATED APPLICATION

This application is based on and claims priority under 35 U.S.C. § 119 to Korean Patent Application No. 10-2024-0131072, filed on Sep. 26, 2024, in the Korean Intellectual Property Office, the disclosure of which is incorporated by reference herein in its entirety.

### BACKGROUND

The inventive concepts relate to non-volatile memory devices, methods of manufacturing the non-volatile memory device, and/or memory systems including the non-volatile memory device, and more particularly, relates to 3-dimensional non-volatile memory devices and/or memory systems including the same.

Consumers demand non-volatile memory devices with higher performance, smaller size, and/or lower price. Therefore, to achieve a non-volatile memory device with a higher degree of integration, a 3-dimensional non-volatile memory device in which a plurality of memory cells are arranged in a vertical direction has been proposed.

### SUMMARY

The inventive concepts provide non-volatile memory devices having operational reliability and/or memory systems including the non-volatile memory device.

According to an example embodiment of the inventive concepts, a non-volatile memory device includes a peripheral circuit structure including a peripheral circuit, the peripheral circuit including a plurality of peripheral circuit transistors, and a cell array structure on the peripheral circuit structure, the cell array structure electrically connected to the peripheral circuit structure, the cell array structure including a common source line layer, a bit line, a bit line wiring insulation layer surrounding the bit line, a cell stack being between the common source line layer and the bit line in a vertical direction, the cell stack including a plurality of gate electrodes and a plurality of interlayer insulation layers alternating in the vertical direction, and a plurality of channel structures extending through the cell stack into the bit line wiring insulation layer, wherein each of the plurality of channel structures includes a channel layer, a bit line pad, and a gate insulation layer, the channel layer electrically connected to the common source line layer, the bit line pad electrically connecting the channel layer to the bit line and being adjacent to one end of the channel layer facing the bit line, and the gate insulation layer covering the channel layer and the bit line pad, and the gate insulation layer includes an insulation protrusion, the insulation protrusion being at a boundary between the bit line wiring insulation layer and the cell stack, the insulation protrusion protruding in a horizontal direction further than a portion of the gate insulation layer penetrating through the cell stack.

According to an example embodiment of the inventive concepts, a non-volatile memory device includes a peripheral circuit structure including a peripheral circuit, the peripheral circuit including a plurality of peripheral circuit transistors, a first cell array structure on the peripheral circuit structure, the first cell array structure electrically connected to the peripheral circuit structure, the first cell array structure including a first bit line, a first bit line wiring insulation layer surrounding the first bit line, a first common source line layer, a first cell stack being between the first bit line and the first common source line layer in a vertical direction, the first cell stack including a plurality of first gate electrodes and a plurality of first interlayer insulation layers alternating in the vertical direction, and a plurality of first channel structures extending through the first cell stack into the first bit line wiring insulation layer, and a second cell array structure on the first cell array structure, the second cell array structure electrically connected to the first cell array structure, the second cell array structure including a second common source line layer, a second bit line, a second bit line wiring insulation layer surrounding the second bit line, a second cell stack being between the second common source line layer and the second bit line in the vertical direction, the second cell stack including a plurality of second gate electrodes and a plurality of second interlayer insulation layers alternating in the vertical direction, and a plurality of second channel structures extending through the second cell stack into the second bit line wiring insulation layer, the first common source line layer and the second common source line layer being between the first cell stack and the second cell stack, each of the plurality of first channel structures includes a first channel layer, a first bit line pad, and a first gate insulation layer, the first channel layer electrically connected to the first common source line layer, the first bit line pad electrically connecting the first channel layer and the first bit line, the first bit line pad being adjacent to one end of the first channel layer facing the first bit line, and the first gate insulation layer covering the first channel layer and the first bit line pad, each of the plurality of second channel structures includes a second channel layer, a second bit line pad, and a second gate insulation layer, the second channel layer electrically connected to the second common source line layer, the second bit line pad electrically connecting the second channel layer and the second bit line, the second bit line pad being adjacent to one end of the second channel layer facing the second bit line, and the second gate insulation layer covering the second channel layer and the second bit line pad, the first gate insulation layer includes a first insulation protrusion, the first insulation protrusion being at a boundary between the first bit line wiring insulation layer and the first cell stack, the first insulation protrusion protruding in a horizontal direction further than a portion of the first gate insulation layer penetrating through the first cell stack, and the second gate insulation layer includes a second insulation protrusion, the second insulating protrusion being at a boundary between the second bit line wiring insulation layer and the second cell stack, the second insulation protrusion protruding in the horizontal direction further than a portion of the second gate insulation layer penetrating through the second cell stack.

According to an example embodiment of the inventive concepts, a memory system includes a non-volatile memory device including a peripheral circuit structure, the peripheral circuit structure including a peripheral circuit, the peripheral circuit including a plurality of peripheral circuit transistors, a first cell array structure on the peripheral circuit structure, a second cell array structure on the first cell array structure, and an input/output pad disposed on the second cell array structure, wherein each of the first cell array structure and the second cell array structure includes a common source line layer, a bit line, a bit line wiring insulation layer surrounding the bit line, a cell stack being between the common source line layer and the bit line in a vertical direction, the cell stack including a plurality of gate electrodes and a plurality of interlayer insulation layers alternating in the vertical direction, and a plurality of channel structures extending through the cell stack into the bit line wiring insulation layer, and a memory controller electrically connected to the non-volatile memory device through the input/output pad and configured to control the non-volatile memory device, wherein the common source line layer of the first cell array structure and the common source line layer of the second cell array structure are arranged between the cell stack of the first cell array structure and the cell stack of the second cell array structure, each of the plurality of channel structures included in each of the first cell array structure and the second cell array structure includes a channel layer, a bit line pad, and a gate insulation layer, the channel layer electrically connected to the common source line layer, the bit line pad electrically connecting the channel layer to the bit line, the bit line pad being adjacent to one end of the channel layer facing the bit line, and the gate insulation layer covering the channel layer and the bit line pad, and the gate insulation layer included in each of the first cell array structure and the second cell array structure includes an insulation protrusion, the insulation protrusion being at a boundary between the bit line wiring insulation layer and the cell stack, the insulation protrusion protruding in a horizontal direction further than a portion of the gate insulation layer penetrating through the cell stack.

### BRIEF DESCRIPTION OF THE DRAWINGS

Example embodiments of the inventive concepts will be more clearly understood from the following detailed description taken in conjunction with the accompanying diagrams in which:

FIG. 1 is a block diagram of a non-volatile memory device according to an example embodiment;

FIG. 2 is a schematic perspective view of a non-volatile memory device according to an example embodiment;

FIG. 3 is an equivalent circuit diagram of a memory cell array of a non-volatile memory device according to an example embodiment;

FIGS. 4A to 4C are cross-sectional views of a non-volatile memory device according to an example embodiment;

FIGS. 5A to 5P are schematic diagrams showing a method of manufacturing a non-volatile memory device, according to an example embodiment;

FIGS. 6A to 6N are cross-sectional views showing a method of manufacturing a non-volatile memory device, according to an example embodiment;

FIGS. 7A and 7B are cross-sectional views of a non-volatile memory device according to some example embodiments;

FIG. 8 is a cross-sectional view of a non-volatile memory device according to an example embodiment;

FIGS. 9A and 9B are cross-sectional views of a non-volatile memory device according to an example embodiment;

FIGS. 10A to 10C are cross-sectional views showing a method of manufacturing a non-volatile memory device, according to an example embodiment;

FIG. 11 is a cross-sectional view of a non-volatile memory device according to embodiments;

FIGS. 12A and 12B are cross-sectional views of a non-volatile memory device according to an example embodiment;

FIGS. 13A to 13C are cross-sectional views showing a method of manufacturing a non-volatile memory device, according to an example embodiment;

FIG. 14 is a cross-sectional view of a non-volatile memory device according to an example embodiment;

FIGS. 15A and 15B are cross-sectional views of a non-volatile memory device according to an example embodiment;

FIGS. 16A and 16B are cross-sectional views showing a method of manufacturing a non-volatile memory device, according to an example embodiment;

FIG. 17 is a cross-sectional view of a non-volatile memory device according to an example embodiment;

FIGS. 18A and 18B are cross-sectional views of a non-volatile memory device according to an example embodiment;

FIGS. 19A to 19C are cross-sectional views showing a method of manufacturing a non-volatile memory device, according to an example embodiment;

FIG. 20 is a cross-sectional view of a non-volatile memory device according to an example embodiment;

FIGS. 21A and 21B are cross-sectional views of a non-volatile memory device according to an example embodiment;

FIGS. 22A to 22C are cross-sectional views showing a method of manufacturing a non-volatile memory device, according to an example embodiment;

FIG. 23 is a cross-sectional view of a non-volatile memory device according to an example embodiment;

FIG. 24 is a schematic view of a memory system including a non-volatile memory device, according to an example embodiment;

FIG. 25 is a schematic perspective view of a memory system including a non-volatile memory device, according to an example embodiment; and

FIG. 26 is a schematic cross-sectional view of a semiconductor package according to an example embodiment.

### DETAILED DESCRIPTION

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

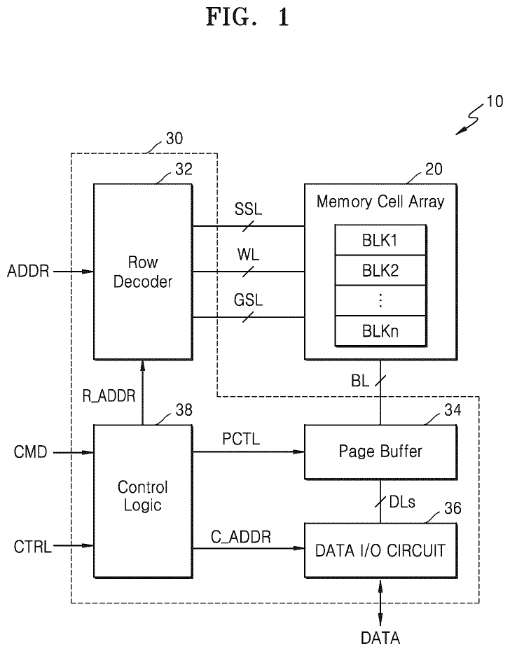

FIG. 1 is a block diagram of a non-volatile memory device according to an example embodiment.

Referring to FIG. 1, a non-volatile memory device 10 may include a memory cell array 20 and a peripheral circuit 30. The memory cell array 20 includes a plurality of memory cell blocks BLK1, BLK2, . . . , and BLKn. The memory cell blocks BLK1, BLK2, . . . , and BLKn may each include a plurality of memory cells. The memory cell blocks BLK1, BLK2, . . . , and BLKn may be connected to the peripheral circuit 30 through a bit line BL, a word line WL, a string select line SSL, and a ground select line GSL.

The peripheral circuit 30 may include a row decoder 32, a page buffer 34, a data input/output circuit 36, and a control logic 38. According to some example embodiments, the peripheral circuit 30 may further include an input/output interface, column logic, a voltage generator, a pre-decoder, a temperature sensor, a command decoder, an address decoder, an amplifier circuit, etc.

The memory cell array 20 may be connected to the page buffer 34 through the bit line BL, and the memory cell array 20 may be connected to the row decoder 32 through the word line WL, the string select line SSL, and the ground select line GSL. In the memory cell array 20, the memory cells included in each of the memory cell blocks BLK1, BLK2, . . . , and BLKn may each be a flash memory cell. The memory cell array 20 may include a 3-dimensional memory cell array. The 3D memory cell array may include a plurality of NAND strings extending in a vertical direction, and the NAND strings may each include a plurality of memory cells connected to a plurality of word lines WL vertically stacked on a substrate, respectively.

The peripheral circuit 30 may receive an address ADDR, a command CMD, and a control signal CTRL from a device outside the non-volatile memory device 10 and may transmit and receive data DATA to and from the device outside the non-volatile memory device 10.

The row decoder 32 may select at least one of the memory cell blocks BLK1, BLK2, . . . , and BLKn in response to an address ADDR from the outside and select the word line WL, the string select line SSL, and the ground select line GSL corresponding to a selected memory cell block. The row decoder 32 may transmit a voltage for performing a memory operation to the word line WL corresponding to the selected memory cell block.

The page buffer 34 may be connected to the memory cell array 20 through the bit line BL. The page buffer 34 may operate as a write driver during a program operation and apply a voltage according to the data DATA to be stored in the memory cell array 20 to the bit line BL and may operate as a sense amplifier during a read operation and sense the data DATA stored in the memory cell array 20. The page buffer 34 may operate according to a control signal PCTL provided from the control logic 38.

The data input/output circuit 36 may be connected to the page buffer 34 through data lines DLs. During a program operation, the data input/output circuit 36 may receive the data DATA from a memory controller (not shown) and provide the data DATA to be programmed to the page buffer 34 based on a column address C_ADDR provided from the control logic 38. The data input/output circuit 36 may provide the data DATA to be read stored in the page buffer 34 to the memory controller based on the column address C_ADDR provided from the control logic 38 during a read operation.

The data input/output circuit 36 may transmit an address or a command input thereto to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller. The control logic 38 may provide a row address R_ADDR to the row decoder 32 and provide the column address C_ADDR to the data input/output circuit 36. The control logic 38 may generate various internal control signals used in the non-volatile memory device 10 in response to the control signal CTRL. For example, the control logic 38 may adjust the level of a voltage provided to the word line WL and the bit line BL when a memory operation like a program operation or an erase operation is performed.

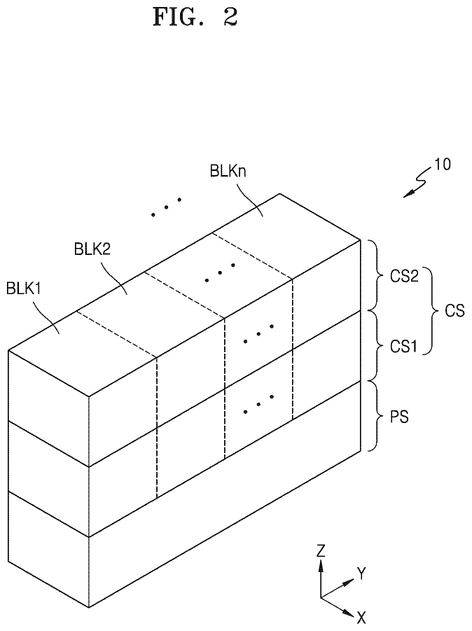

FIG. 2 is a schematic perspective view of a non-volatile memory device according to an example embodiment.

Referring to FIG. 2, the non-volatile memory device 10 includes a cell array structure CS and a peripheral circuit structure PS overlapping each other in a vertical direction (Z direction). The cell array structure CS may include the memory cell array 20 described above with reference to FIG. 1. The peripheral circuit structure PS may include the peripheral circuit 30 described above with reference to FIG. 1.

The cell array structure CS may include a first cell array structure CS1 and a second cell array structure CS2 that overlap each other in the vertical direction. For example, the non-volatile memory device 10 may include a peripheral circuit structure PS, the first cell array structure CS1, and the second cell array structure CS2 that are sequentially stacked in the vertical direction (Z direction). The first cell array structure CS1 and the second cell array structure CS2 may each include the plurality of memory cell blocks BLK1, BLK2, . . . , and BLKn. The memory cell blocks BLK1, BLK2, . . . , and BLKn may each include 3-dimensionally arranged memory cells. According to some example embodiments, the plurality of memory cell blocks BLK1, BLK2, . . . , and BLKn included in the first cell array structure CS1 and the plurality of memory cell blocks BLK1, BLK2, . . . , and BLKn included in the second cell array structure CS2 may have structures that are symmetrical to each other in the vertical direction (Z direction). According to some example embodiments, at least a portion of the first cell array structure CS1 and at least a portion of the second cell array structure CS2 may have structures that are symmetrical to each other in the vertical direction (Z direction). For example, except for some components for electrically connecting the plurality of memory cell blocks BLK1, BLK2, . . . , and BLKn included in each of the first cell array structure CS1 and the second cell array structure CS2 and the peripheral circuit structure PS, the first cell array structure CS1 and the second cell array structure CS2 may have structures that are symmetrical to each other in the vertical direction (Z direction).

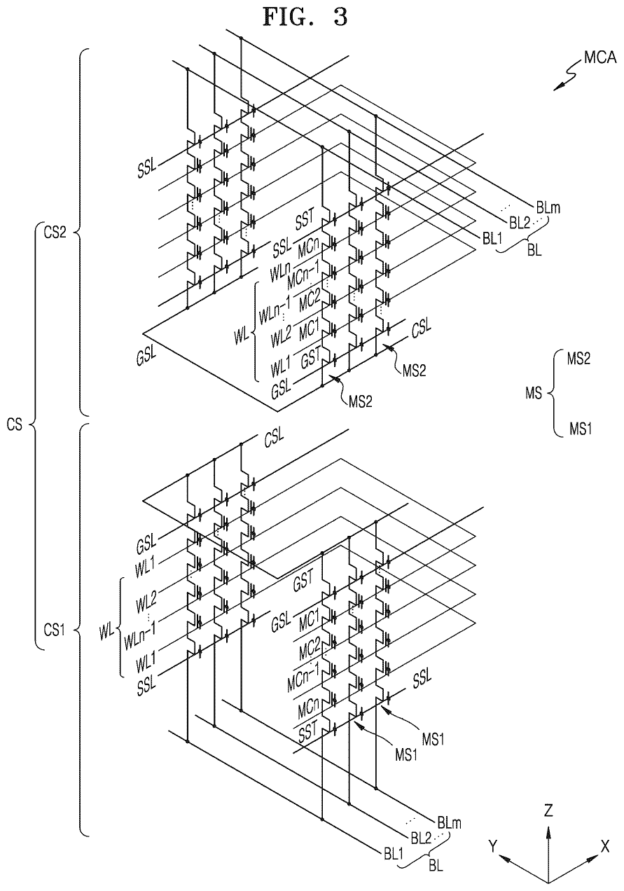

FIG. 3 is an equivalent circuit diagram of a memory cell array of a non-volatile memory device according to an example embodiment.

Referring to FIG. 3, a memory cell array MCA may be configured in a cell array structure CS including the first cell array structure CS1 and the second cell array structure CS2. The memory cell array MCA may include at least a portion of the memory cell array 20 described above with reference to FIG. 1. According to some example embodiments, the memory cell array MCA may include at least a portion of one of the plurality of memory cell blocks BLK1, BLK2, . . . , and BLKn included in the memory cell array 20 described with reference to FIG. 1. The memory cell array MCA may include a plurality of first memory cell strings MS1 and a plurality of second memory cell strings MS2. The plurality of first memory cell strings MS1 may be configured in the first cell array structure CS1, and the plurality of second memory cell strings MS2 may be configured in the second cell array structure CS2.

The plurality of first memory cell strings MS1 and the plurality of second memory cell strings MS2 may each extend in the vertical direction (Z direction). The memory cell array MCA may include, in each of the first cell array structure CS1 having configured therein the plurality of first memory cell strings MS1 and the second cell array structure CS2 having configured therein the plurality of second memory cell strings MS2, a plurality of word lines WL (WL1, WL2, . . . , WLn−1, and WLn), a plurality of bit lines BL (BL1, BL2, . . . , and BLm), at least one string select line SSL, at least one ground select line GSL, and a common source line CSL. Each of the plurality of word lines (WL: WL1, WL2, . . . , WLn−1, and WLn) may extend along a first horizontal direction (X direction), and each of the plurality of bit lines (BL: BL1, BL2, . . . , and BLm) may extend along a second horizontal direction (Y direction) orthogonal to the first horizontal direction (X direction). Each of at least one string select line (SSL) and at least one ground select line (GSL) may extend in the same direction as the plurality of word lines (WL: WL1, WL2, . . . , WLn−1, and WLn), for example, along the first horizontal direction (X direction). The memory cell strings MS may be formed between the bit lines BL (BL1, BL2, . . . , and BLm) and the common source line CSL. FIG. 3 illustrates an example in which each of a plurality of first memory cell strings (MS1) and a plurality of second memory cell strings (MS2) includes one string selection line (SSL), but the inventive concepts are not limited thereto. For example, each of the plurality of first memory cell strings (MS1) and the plurality of second memory cell strings (MS2) may include two or more string select lines (SSL).

Each of the plurality of first memory cell strings (MS1) and the plurality of second memory cell strings (MS2) may include a string select transistor (SST), a ground select transistor (GST), and a plurality of memory cell transistors (MC1, MC2, . . . , MCn−1, MCn). A drain region of the string select transistor SST may be connected to the bit lines BL (BL1, BL2, . . . , and BLm), and a source region of the ground select transistor GST may be connected to the common source line CSL. The common source line CSL may be a region in which source regions of a plurality of ground select transistors GST are connected in common.

The string select transistor SST may be connected to the string select line SSL, and the ground select transistor GST may be connected to the ground select line GSL. The memory cell transistors MC1, MC2, . . . , MCn−1, and MCn may be connected to the word lines WL (WL1, WL2, . . . , WLn−1, and WLn), respectively.

The plurality of first memory cell strings MS1 and the plurality of second memory cell strings MS2 may be symmetrical to each other in the vertical direction (Z direction). In other words, transistors included in the plurality of first memory cell strings MS1 and transistors included in the plurality of second memory cell strings MS2 may be arranged in orders opposite to each other in the vertical direction (Z direction). For example, in the vertical direction (Z direction), the plurality of second memory cell strings MS2 may be arranged in the order of the ground select transistor GST, the plurality of memory cell transistors MC1, MC2, . . . , MCn−1, and MCn, and the string select transistor SST, and the plurality of first memory cell strings MS1 may be arranged in the order of the string select transistor SST, a plurality of memory cell transistors MCn, MCn−1, . . . , MC2, and MC1, and the ground select transistor GST.

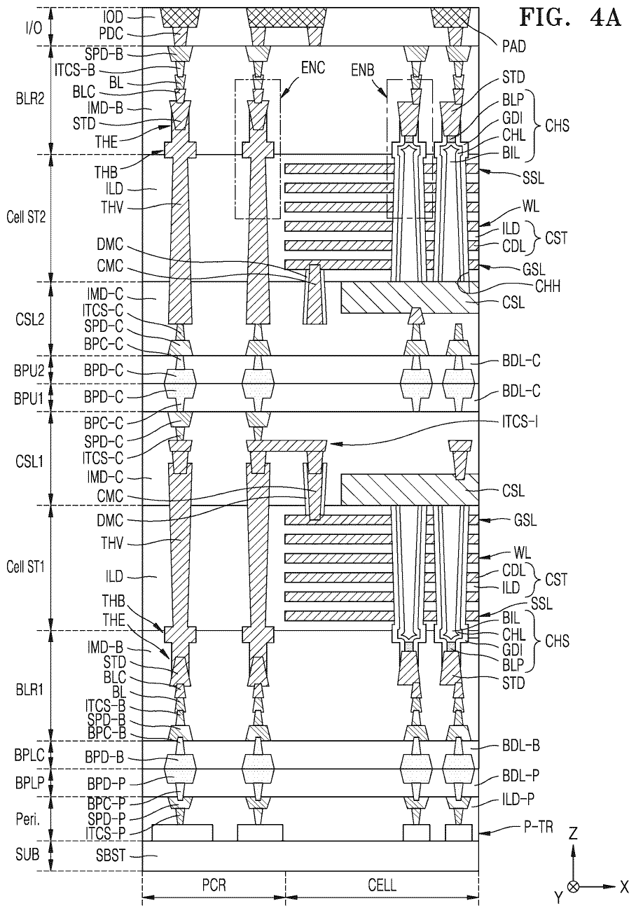

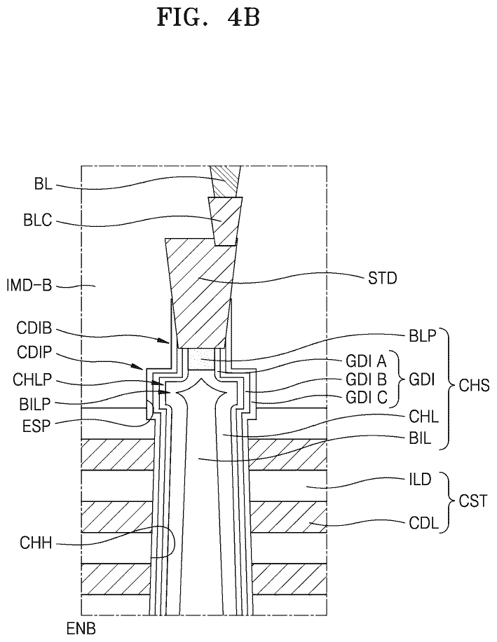

FIGS. 4A to 4C are cross-sectional views of a non-volatile memory device according to an example embodiment. In detail, FIG. 4B is an enlarged cross-sectional view of a portion ENB of FIG. 4A, and FIG. 4C is an enlarged cross-sectional view of a portion ENC of FIG. 4A.

Referring to FIG. 2 and FIG. 4A to FIG. 4C together, a non-volatile memory device 10 includes a substrate region SUB and a peripheral circuit region Peri., a lower peripheral bonding region BPLP, an upper peripheral bonding region BPLC, a first bit line region BLR1, a first cell stack region Cell ST1, a first common source region CSL1, a lower cell bonding region BPU1, an upper cell bonding region BPU2, a second common source region CSL2, a second cell stack region Cell ST2, a second bit line region BLR2, and an input/output region I/O.

The substrate region SUB and the peripheral circuit region Peri. may constitute the peripheral circuit structure PS. The first bit line region BLR1, the first cell stack region Cell ST1, and the first common source region CSL1 may constitute the first cell array structure CS1. The second common source region CSL2, the second cell stack region Cell ST2, and the second bit line region BLR2 may constitute the second cell array structure CS2. In the first cell array structure CS1, the first bit line region BLR1 and the first common source region CSL1 are arranged above and below the first cell stack region Cell ST1. However, in the second cell array structure CS2, the second bit line region BLR2 and the second common source region CSL2 may be arranged above and below the second cell stack region Cell ST2.

The lower peripheral bonding region BPLP positioned above the peripheral circuit area Peri. and the upper peripheral bonding region BPLC positioned below the first bit line region BLR1 are bonded, and thus the peripheral circuit structure PS and the first cell array structure CS1 may be bonded to each other. The lower cell bonding region BPU1 positioned above the first common source region CSL1 and the upper cell bonding region BPU2 positioned below the second common source region CSL2 are bonded, and thus the first cell array structure CS1 and the second cell array structure CS2 may be bonded to each other to form the cell array structure CS. In other words, the lower peripheral bonding region BPLP and the upper peripheral bonding region BPLC are bonded, and thus the peripheral circuit structure PS and the cell array structure CS may be bonded to each other. The input/output region I/O that electrically connects the non-volatile memory device 10 and an external device may be arranged on the cell array structure CS.

The substrate region SUB may include a substrate SBST. The substrate SBST may include a semiconductor material such as a group IV semiconductor material, a group III-V semiconductor material, a group II-VI semiconductor material, and a group II-VI oxide semiconductor material. The group IV semiconductor material may include, for example, silicon (Si), germanium (Ge), or silicon-germanium (SiGe). The group III-V semiconductor material may include, for example, gallium arsenide (GaAs), indium phosphide (InP), gallium phosphide (GaP), indium arsenide (InAs), indium antimonide (InSb), or indium gallium arsenide (InGaAs). The group II-VI semiconductor material may include, for example, zinc telluride (ZnTe) or cadmium sulfide (CdS). The substrate SBST may be a bulk wafer or an epitaxial layer. The substrate SBST may be provided as a bulk wafer or an epitaxial layer. According to some example embodiments, the substrate SBST may include a silicon-on-insulator (SOI) substrate or a germanium-on-insulator (GeOI) substrate. An active region may be defined in the substrate SBST by a device isolation film, and a plurality of peripheral circuit transistors P-TR may be formed on the active region. Source/drain regions constituting the plurality of peripheral circuit transistors P-TR may be formed in a portion of the substrate SBST.

The peripheral circuit region Peri. may include the plurality of peripheral circuit transistors P-TR constituting the peripheral circuit 30 described with reference to FIG. 1. In the peripheral circuit region Peri., a plurality of peripheral circuit gates constituting the plurality of peripheral circuit transistors P-TR may be arranged.

The peripheral circuit region Peri. may include a plurality of peripheral circuit wiring layers SPD-P and a plurality of peripheral circuit contacts ITCS-P. The plurality of peripheral circuit wiring layers SPD-P may be electrically connected to the substrate SBST and/or the plurality of peripheral circuit transistors P-TR via the plurality of peripheral circuit contacts ITCS-P. The plurality of peripheral circuit wiring layers SPD-P and the plurality of peripheral circuit contacts ITCS-P may each include a conductive material such as copper (Cu), aluminum (Al), tungsten (W), silver (Ag), gold (Au), or a combination thereof.

A peripheral circuit insulation structure ILD-P covering the plurality of peripheral circuit transistors P-TR and surrounding the plurality of peripheral circuit wiring layers SPD-P and the plurality of peripheral circuit contacts ITCS-P may be formed on the substrate SBST. The peripheral circuit insulation structure ILD-P may include an insulation material including silicon oxide, silicon nitride, a low-k material, or a combination thereof. The low-k material is a material having a lower dielectric constant than that of silicon oxide and may include, for example, phosphosilicate glass (PSG), borophosphosilicate glass (BPSG), fluorosilicate glass (FSG), organosilicate glass (OSG), spin-on-glass (SOG), spin-on-polymer, or a combination thereof. According to some example embodiments, the peripheral circuit insulation structure ILD-P may include an ultra-low k (ULK) film having an ultra-low dielectric constant K from about 2.2 to about 2.4. The ULK film may include a SiOC or a SiCOH.

The first bit line region BLR1 may include a connection wiring layer SPD-B, a bit line interconnect structure ITCS-B connected to the connection wiring layer SPD-B, a bit line BL connected to the bit line interconnect structure ITCS-B, a bit line contact BLC connected to the bit line BL, a stud STD connected to the bit line contact BLC, and a bit line wiring insulation layer IMD-B surrounding the connection wiring layer SPD-B, the bit line interconnect structure ITCS-B, the bit line BL, the bit line contact BLC, and the stud STD. Bit lines BL may be spaced apart from each other in the first horizontal direction (X direction) and may extend in the second horizontal direction (Y direction), but the inventive concepts are not limited thereto. The connection wire layer SPD-B, the bit line interconnect structure ITCS-B, the bit line BL, the bit line contact BLC, and the stud STD may each include metal, conductive metal nitride, metal silicide, conductive polysilicon, or a combination thereof. The bit line wiring insulation layer IMD-B may include an insulation material including silicon oxide, silicon nitride, a low-k material, or a combination thereof.

The first cell stack region Cell ST1 may include a plurality of gate electrodes CDL, which are arranged and spaced apart from each other in the vertical direction (Z direction), and an interlayer insulation layer ILD. The plurality of gate electrodes CDL may include a conductive material. The interlayer insulation layer ILD may include an insulation material. The plurality of gate electrodes CDL may be arranged in the cell region CELL. A through via THV that penetrates through the interlayer insulation layer ILD may be formed in a peripheral connection region PCR adjacent to the cell region CELL in the first horizontal direction X direction. The interlayer insulation layer ILD may surround the plurality of gate electrodes CDL and the through via THV. According to some example embodiments, in the cell region CELL, a plurality of interlayer insulation layers ILD may fill in between the plurality of gate electrodes CDL. For example, in the cell region CELL, the plurality of gate electrodes CDL and the plurality of interlayer insulation layers ILD may be alternately arranged in the vertical direction (Z direction). In the cell region CELL, the plurality of gate electrodes CDL and the plurality of interlayer insulation layers ILD alternately arranged in the vertical direction (Z direction) may be referred to as a cell stack CST. A portion of the interlayer insulation layer ILD disposed in the cell region CELL may be referred to as a cell interlayer insulation layer, and a portion of the interlayer insulation layer ILD disposed in the peripheral connection region PCR may be referred to as a peripheral interlayer insulation layer.

A plurality of cell channel structures CHS extending in the vertical direction (Z direction) through the cell stack CST including the plurality of gate electrodes CDL and the plurality of interlayer insulation layers ILD may be arranged in the cell region CELL. The plurality of cell channel structures CHS may extend through the cell stack CST into the bit line wiring insulation layer IMD-B. In the first cell stack region Cell ST1, a first memory cell string (MS1 of FIG. 3) including a plurality of memory cells may be formed along each of the plurality of cell channel structures CHS. According to some example embodiments, the plurality of gate electrodes CDL may correspond to at least one string select line SSL, the word lines WL (WL1, WL2, . . . , WLn−1, and WLn) and at least one ground select line GSL constituting the first memory cell string MS1 shown in FIG. 3. For example, a gate electrode CDL positioned closest to the first common source region CSL1 may function as the ground select line GSL, a gate electrode CDL positioned closest to the first bit line region BLR1 may function as the string select line SSL, and remaining gate electrodes CDL may function as the word lines WL. Therefore, the first memory cell string MS1 in which the ground select transistor GST, the string select transistor SST, and memory cell transistors MC1, MC2, . . . MCn−1, and MCn are connected in series therebetween as shown in FIG. 3 may be provided.

The plurality of cell channel structures CHS may each include a gate insulation layer GDI, a channel layer CHL, a buried insulation layer BIL, and a bit line pad BLP. The gate insulation layer GDI and the channel layer CHL may be sequentially arranged on the inner wall of a channel hole CHH. The bit line pad BLP may be disposed at one end of the channel layer CHL facing the bit line BL. For example, the bit line pad BLP may be located within the bit line wiring insulation layer IMD-B. The gate insulation layer GDI may conformally cover the inner wall of the channel hole CHH penetrating through the cell stack CST including the plurality of gate electrodes CDL and the plurality of interlayer insulation layers ILD, the bit line pad BLP may be positioned on the gate insulation layer GDI at one end of the channel hole CHH facing the bit line BL, and the channel layer CHL may conformally cover the gate insulation layer GDI and the bit line pad BLP. The gate insulation layer GDI may conformally cover and surround the channel layer CHL and the bit line pad BLP. The channel hole CHH may extend into the bit line wiring insulation layer IMD-B to the stud STD. A cell channel structure CHS may be connected to a stud STD. The bit line pad BLP may be interposed between the channel layer CHL and the stud STD and electrically connect the channel layer CHL and the stud STD. According to some example embodiments, the bit line pad BLP and the stud STD may be formed to be aligned in the vertical direction (Z direction). For example, the bit line pad BLP may be in contact with the bottom surface of the stud STD, but may not be in contact with the side surface of the stud STD. According to some example embodiments, the bit line pad BLP may contact the entire bottom surface of the stud STD.

According to some example embodiments, the bit line pad BLP may include conductive polysilicon. For example, the bit line pad BLP may include n+ polysilicon that is heavily doped with n-type impurities to provide conductivity. The bit line BL may be electrically connected to the channel layer CHL through the bit line contact BLC, the stud STD, and the bit line pad BLP. The buried insulation layer BIL may be disposed on the channel layer CHL to fill the remaining space of the channel hole CHH. The buried insulation layer BIL may fill the space defined by the channel layer CHL. According to some example embodiments, the buried insulation layer BIL may be omitted and the channel layer CHL may be formed in a pillar-like shape that fills the remaining portion of the channel hole CHH.

The gate insulation layer GDI may have a structure including a tunneling dielectric film GDIA, a charge storage film GDIB, and a blocking dielectric film GDIC sequentially arranged on the outer wall of the channel layer CHL. The relative thicknesses of the tunneling dielectric film GDIA, the charge storage film GDIB, and the blocking dielectric film GDIC forming the gate insulation layer GDI are not limited to those shown in FIG. 4B and may vary in various ways.

The tunneling dielectric film GDIA may include silicon oxide, hafnium oxide, aluminum oxide, zirconium oxide, tantalum oxide, etc. The charge storage film GDIB is a region in which electrons that passed through the tunneling dielectric film GDIA from the channel layer CHL may be stored and may include silicon nitride, boron nitride, silicon boron nitride, or polysilicon doped with impurities. The blocking dielectric film GDIC may include silicon oxide, silicon nitride, or metal oxide having a higher permittivity than silicon oxide. The metal oxide may include hafnium oxide, aluminum oxide, zirconium oxide, tantalum oxide, or a combination thereof.

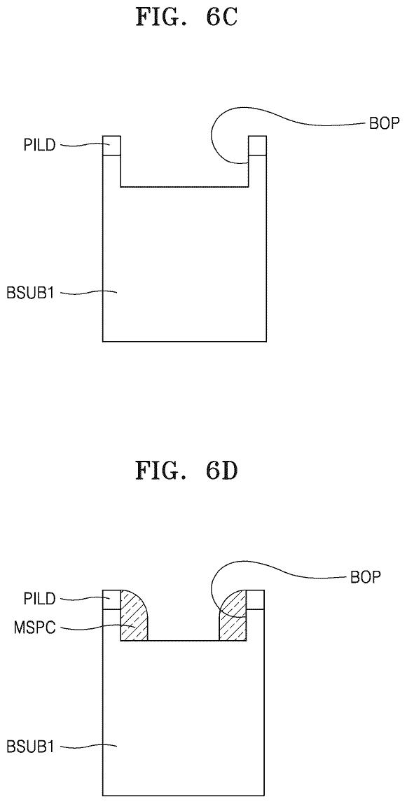

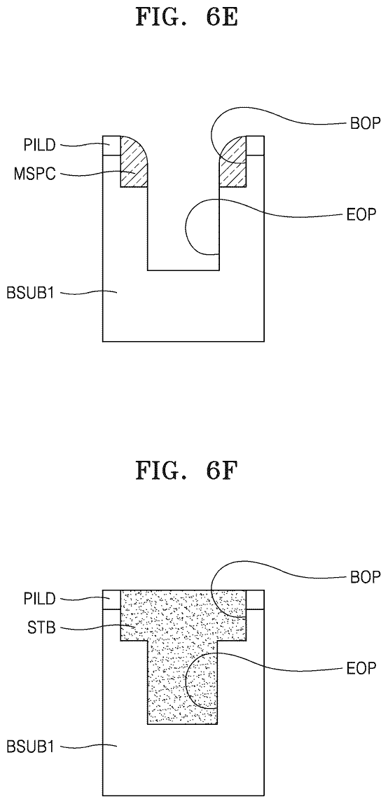

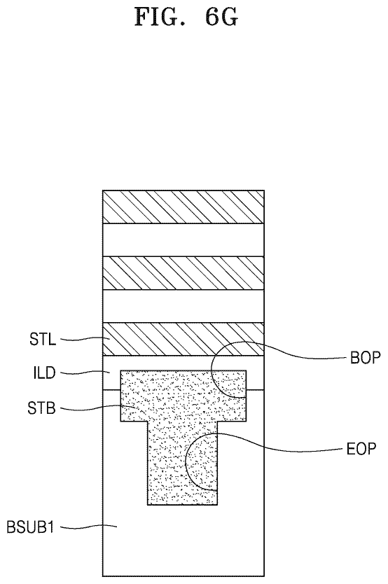

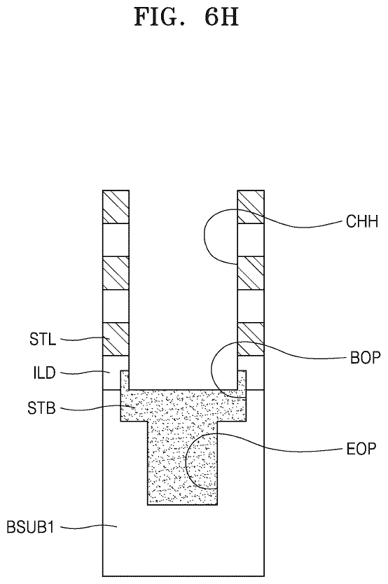

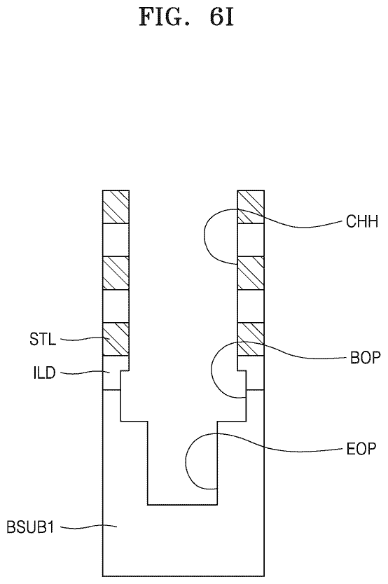

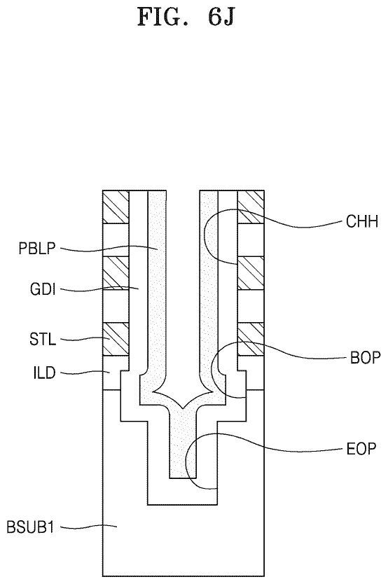

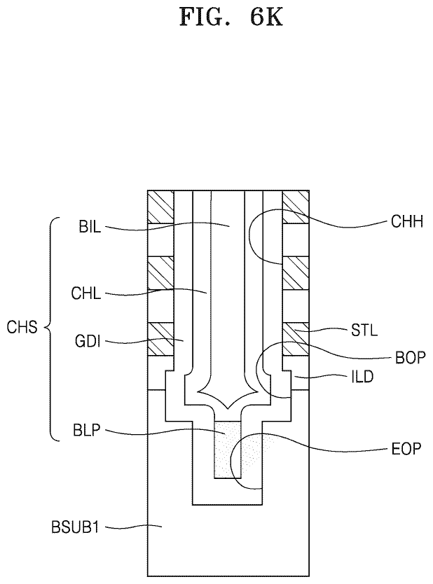

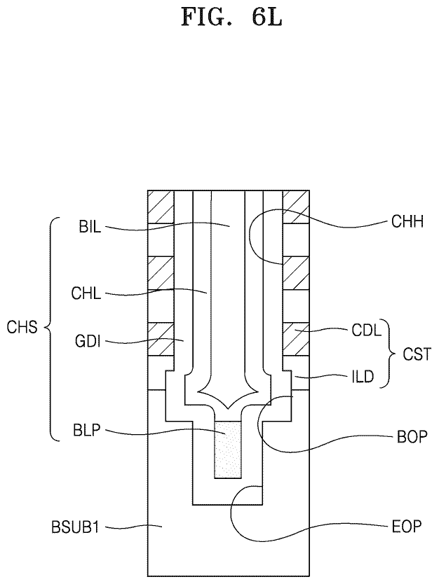

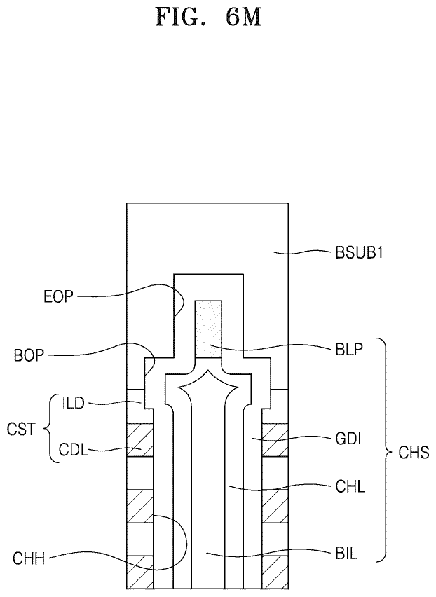

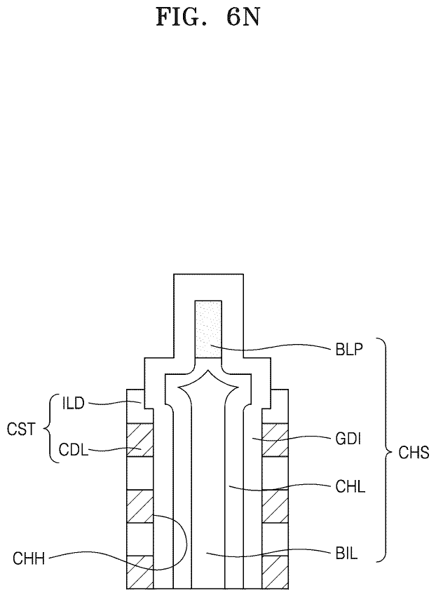

The channel hole CHH may have an expanded space ESP corresponding to a base opening BOP shown in FIGS. 6C to 6N. The horizontal width of the expanded space ESP may be greater than the horizontal widths of other portions of the channel hole CHH. In other words, the expanded space ESP may be a space that expands from another portion of the channel hole CHH in a horizontal direction. The expanded space ESP of the channel hole CHH may be located at the boundary between the cell stack CST and the bit line wiring insulation layer IMD-B. For example, the expanded space ESP of the channel hole CHH may be disposed across the cell stack CST and the bit line wiring insulation layer IMD-B. The expanded space ESP of the channel hole CHH may be separated from the plurality of gate electrodes CDL. For example, a portion of the interlayer insulation layer ILD may be disposed between the gate electrode CDL most adjacent to the bit line BL from among the plurality of gate electrodes CDL and the expanded space ESP of the channel hole CHH. The gate insulation layer GDI, the channel layer CHL, and the buried insulation layer BIL may respectively have an insulation protrusion CDIP, a channel protrusion CHLP, and a buried protrusion BILP that protrude in a horizontal direction, in correspondence to the expanded space ESP of the channel hole CHH. The channel protrusion CHLP may cover the buried protrusion BILP, and the insulation protrusion CDIP may cover the channel protrusion CHLP. The gate insulation layer GDI may have an insulation extension CDIB extending from the insulation protrusion CDIP toward the bit line BL into the bit line wiring insulation layer IMD-B. The insulation extension CDIB may wrap around the side of the bit line pad BLP. The stud STD may be connected to the bit line pad BLP. The insulation extension CDIB may cover a portion of the side surface of the stud STD adjacent to the bit line pad BLP.

From among the portions of the gate insulation layer GDI, the channel layer CHL, and the buried insulation layer BIL penetrating through the cell stack CST, portions excluding the insulation protrusion CDIP, the channel protrusion CHLP, and the buried protrusion BILP may be referred to as body portions. For example, the gate insulation layer GDI may include a body portion of the gate insulation layer GDI, the insulation protrusion CDIP, and the insulation extension CDIB, the channel layer CHL may include a body portion of the channel layer CHL, and the channel protrusion CHLP, and the buried insulation layer BIL may include a body portion of the buried insulation layer BIL and the buried protrusion BILP.

The through via THV may include a via protrusion THB and a via extension THE. A space filled with the via protrusion THB may be formed in the same manner as the expanded space ESP of the channel hole CHH. The via extension THE extends from the via protrusion THB toward the stud STD and may extend with or along the stud STD. The via protrusion THB may be positioned at the same vertical or substantially similar level as each of the insulation protrusion CDIP, the channel protrusion CHLP, and the buried protrusion BILP, and the via extension THE may be positioned at the same or substantially similar vertical level as the insulation extension CDIB. The via protrusion THB may be disposed across the interlayer insulation layer ILD and the bit line wiring insulation layer IMD-B, and the via extension THE may extend from the via protrusion THB toward the bit line BL into the bit line wiring insulation layer IMD-B. From among portions of the through via THV that penetrate through the interlayer insulation layer ILD, a portion excluding the via protrusion THB may be referred to as a body portion. The through via THV may include a body portion of the through via THV, the via protrusion THB, and the via extension THE.

The first common source region CSL1 includes a common source line layer CSL and a source wiring insulation layer IMD-C surrounding the common source line layer CSL. The common source line layer CSL may be connected to the channel layer CHL of a plurality of channel structures CHS. The common source line layer CSL may include a semiconductor material like a group IV semiconductor material, a group III-V semiconductor material, and a group II-VI semiconductor material. For example, the common source line layer CSL may include at least one of silicon (Si), germanium (Ge), silicon germanium (SiGe), gallium arsenide (GaAs), indium gallium arsenide (InGaAs), aluminum gallium arsenide (AlGaAs), or a mixture thereof. Also, the common source line layer CSL may include a semiconductor doped with n-type impurities. Further, the common source line layer CSL may have a crystal structure including at least one selected from among monocrystalline, amorphous, and polycrystalline. According to some example embodiments, the common source line layer CSL may include a semiconductor material that does not contain carbon. For example, the common source line layer CSL may include polysilicon. According to some example embodiments, the common source line layer CSL may include polysilicon that does not contain carbon. According to some embodiments, the common source line layer CSL may include polysilicon doped with n-type impurities.

The first common source region CSL1 may include a gate contact plug CMC penetrating through a portion of the source wiring insulation layer IMD-C. The gate contact plug CMC may be connected to each of a plurality of gate electrodes CDL by penetrating through a portion of the source wiring insulation layer IMD-C and a portion of the interlayer insulation layer ILD. According to some example embodiments, a protective insulation layer DMC surrounding the gate contact plug CMC may be formed. The protective insulation layer DMC may be disposed between the gate contact plug CMC and a portion of the source wiring insulation layer IMD-C, between the gate contact plug CMC and a portion of the interlayer insulation layer ILD, and between the gate contact plug CMC and a gate electrode CDL that is not connected to the gate contact plug CMC from among the plurality of gate electrodes CDL.

An internal interconnect structure ITCS-I may be connected to one end of the gate contact plug CMC opposite to the plurality of gate electrodes CDL. The internal interconnect structure ITCS-I may consist of or include a wiring layer and/or a contact surrounded by the source wiring insulation layer IMD-C. The internal interconnect structure ITCS-I may electrically connect the gate contact plug CMC and the through via THV. The through via THV may extend from the first cell stack region Cell ST1 into the first common source region CSL1. For example, the through via THV may penetrate through the interlayer insulation layer ILD and a portion of the source wiring insulation layer IMD-C.

An internal contact ITCS-C surrounded by the source wiring insulation layer IMD-C and an internal wiring layer SPD-C connected to the internal contact ITCS-C may be formed on the internal interconnect structure ITCS-I.

The second common source region CSL2, the second cell stack region Cell ST2, and the second bit line region BLR2 may have structures that are symmetrical with respect to the first common source region CSL1, the first cell stack region Cell ST1, and the first bit line region BLR1, respectively, and may have the same or substantially similar configurations as the first common source region CSL1, the first cell stack region Cell ST1, and the first bit line region BLR1, respectively. Therefore, descriptions identical to those already given above will be omitted. Although FIG. 4A shows that the internal interconnect structure ITCS-I included in the first common source region CSL1 is not included in the second common source region CSL2, it is merely an example, and the inventive concepts are not limited thereto. For example, the second common source region CSL2 may further include an interconnect structure that interconnects the gate contact plug CMC included in the second common source region CSL2 and the internal wiring layer SPD-C, and the gate contact plug CMC included in the second common source region CSL2 may be electrically connected to an internal wiring layer SPD-C located at a different portion from that of the internal wiring layer SPD-C shown in FIG. 4A (e.g., a different portion in the second horizontal direction (Y direction).

The lower peripheral bonding region BPLP disposed above the peripheral circuit region Peri. may include a lower peripheral bonding contact BPC-P, a lower peripheral bonding pad BPD-P, and a lower peripheral insulation layer BDL-P surrounding the lower peripheral bonding contact BPC-P and the lower peripheral bonding pad BPD-P. The lower peripheral bonding contact BPC-P may electrically connect a peripheral circuit wiring layer SPD-P and the lower peripheral bonding pad BPD-P. The lower peripheral bonding contact BPC-P and the lower peripheral bonding pad BPD-P may each include a conductive material, which may include copper (Cu), gold (Au), silver (Ag), aluminum (Al), tungsten (W), titanium (Ti), tantalum (Ta), or a combination thereof. For example, the lower peripheral bonding pad BPD-P may include a material containing copper (Cu). For example, the lower peripheral insulation layer BDL-P may include silicon oxide or silicon carbon nitride (SiCN). According to some example embodiments, the top surface of the lower peripheral bonding pad BPD-P and the top surface of the lower peripheral insulation layer BDL-P may be coplanar.

The upper peripheral bonding region BPLC disposed on the lower peripheral bonding region BPLP may include an upper peripheral bonding contact BPC-B, an upper peripheral bonding pad BPD-B, and an upper peripheral insulation layer BDL-B surrounding the upper peripheral bonding contact BPC-B and the upper peripheral bonding pad BPD-B. The upper peripheral bonding contact BPC-B may electrically connect the connection wiring layer SPD-B of the first bit line region BLR1 and the upper peripheral bonding pad BPD-B. The upper peripheral bonding contact BPC-B, the upper peripheral bonding pad BPD-B, and the upper peripheral insulation layer BDL-B may be generally similar to the lower peripheral bonding contact BPC-P, the lower peripheral bonding pad BPD-P, and the lower peripheral insulation layer BDL-P, respectively. According to some example embodiments, the bottom surface of the upper peripheral bonding pad BPD-B and the bottom surface of the upper peripheral insulation layer BDL-B may be coplanar.

The lower peripheral bonding region BPLP and the upper peripheral bonding region BPLC may be bonded to each other through a hybrid bonding. The lower peripheral bonding pad BPD-P and the upper peripheral bonding pad BPD-B may face each other, expand to contact each other by heat, and be diffusion-bonded to each other to be integrated with each other through diffusion of metal atoms, thereby forming a combined bonding pad. The lower peripheral insulation layer BDL-P and the upper peripheral insulation layer BDL-B may be joined by forming a covalent bond.

The lower cell bonding region BPU1 disposed over the first common source region CSL1 and the upper cell bonding region BPU2 disposed on the lower cell bonding region BPU1 may each include a cell bonding contact BPC-C, a cell bonding pad BPD-C, and a cell insulation layer BDL-C surrounding the cell bonding contact BPC-C and the cell bonding pad BPD-C. The cell bonding contact BPC-C of the lower cell bonding region BPU1 may electrically connect the internal wiring layer SPD-C and the cell bonding pad BPD-C of the first common source region CSL1, and the cell bonding contact BPC-C of the upper cell bonding region BPU2 may electrically connect the internal wiring layer SPD-C and the cell bonding pad BPD-C of the second common source region CSL2.

The cell bonding contact BPC-C, the cell bonding pad BPD-C and the cell insulation layer BDL-C are generally similar to the lower peripheral bonding contact BPC-P, the lower peripheral bonding pad BPD-P, and the lower peripheral insulation layer BDL-P or the upper peripheral bonding contact BPC-B, the upper peripheral bonding pad BPD-B, and the upper peripheral insulation layer BDL-B, and thus descriptions identical to those given above are omitted.

The input/output region I/O includes an input/output pad PAD, an input/output contact PDC, and an input/output insulation layer IOD surrounding the input/output pad PAD and the input/output contact PDC. The input/output contact PDC may electrically connect the connection wiring layer SPD-B of the second bit line region BLR2 and the input/output pad PAD. The input/output pad PAD may be electrically connected to a bit line BL of the second bit line region BLR2. The input/output pads PAD and input/output contact PDC may each include metal, conductive metal nitride, metal silicide, conductive polysilicon, or a combination thereof. The input/output insulation layer IOD may include an insulation material including silicon oxide, silicon nitride, a low-k material, or a combination thereof.

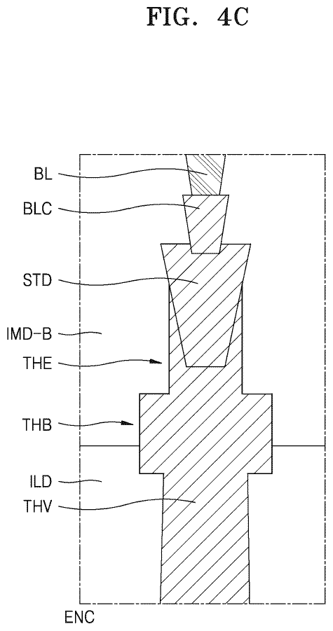

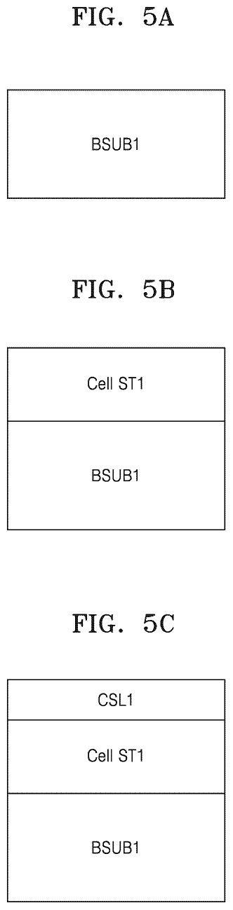

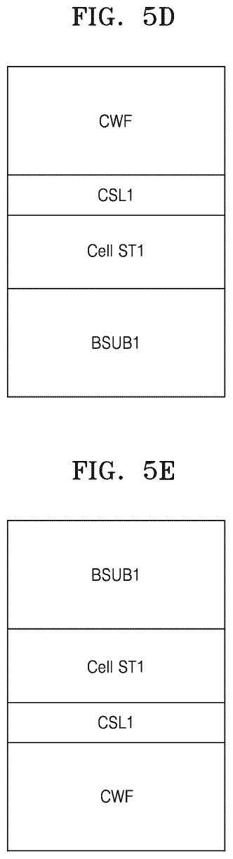

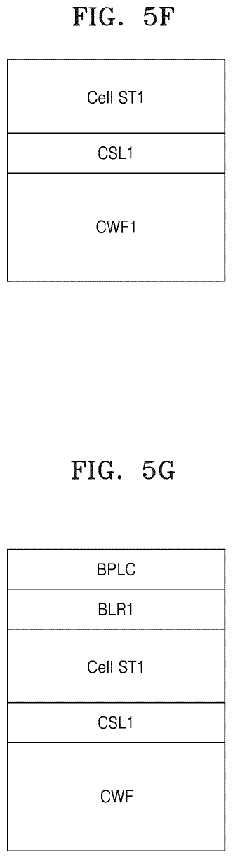

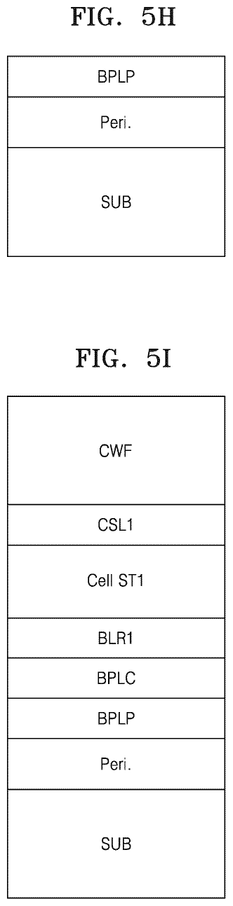

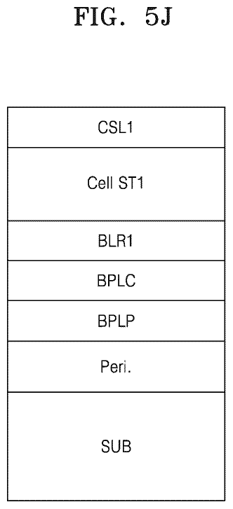

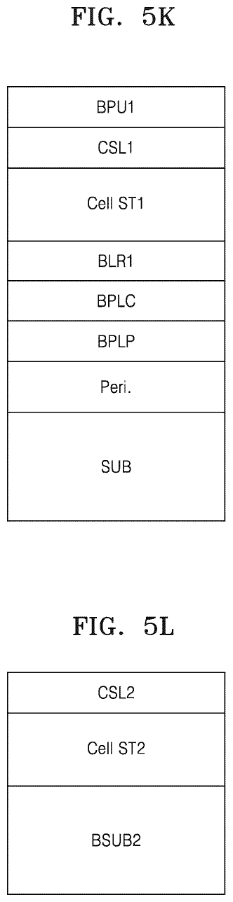

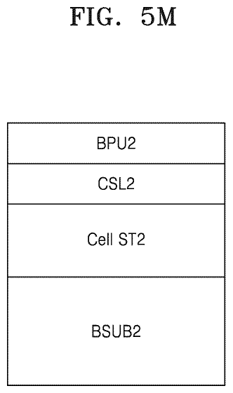

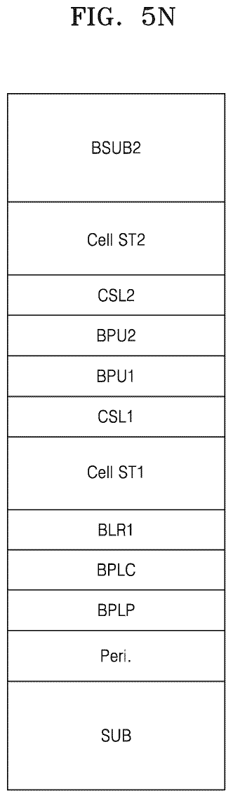

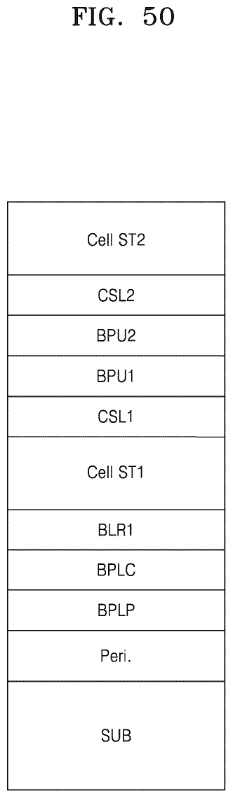

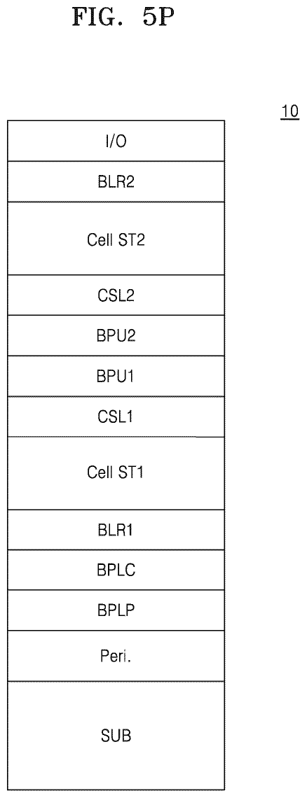

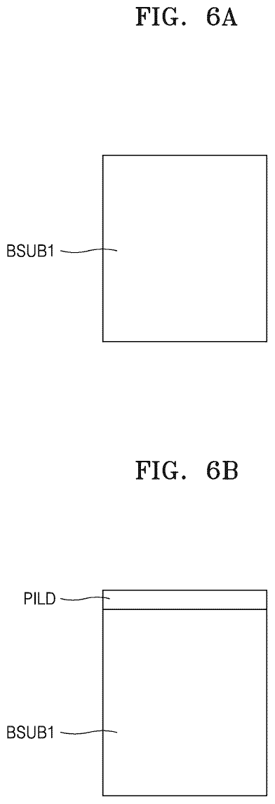

FIGS. 5A to 5P are schematic diagrams showing a method of manufacturing a non-volatile memory device, according to an example embodiment. FIGS. 5A to 5P illustrate in a simplified manner the substrate region SUB, the peripheral circuit region Peri., the lower peripheral bonding region BPLP, the upper peripheral bonding region BPLC, the first bit line region BLR1, the first cell stack region Cell ST1, the first common source region CSL1, the lower cell bonding region BPU1, the upper cell bonding region BPU2, the second common source region CSL2, the second cell stack region Cell ST2, the second bit line region BLR2, and the input/output region I/O shown in FIG. 4A.

Referring to FIG. 5A, a first base substrate region BSUB1 is prepared. The first base substrate region BSUB1 may be, but is not limited to, a semiconductor substrate. According to some example embodiments, the first base substrate region BSUB1 may be a bulk wafer.

Referring to FIG. 5B, the first cell stack region Cell ST1 is formed on the first base substrate region BSUB1. For example, the first cell stack region Cell ST1 including the plurality of gate electrodes CDL, the interlayer insulation layer ILD, and the plurality of cell channel structures CHS as shown in FIG. 4A may be formed on the first base substrate region BSUB1.

Referring to FIG. 5C, the first common source region CSL1 is formed on the first cell stack region Cell ST1. For example, the first common source region CSL1 including the common source line layer CSL, the source wiring insulation layer IMD-C, the gate contact plug CMC, the internal interconnect structure ITCS-I, the internal contact ITCS-C, and the internal wiring layer SPD-C as shown in FIG. 4A may be formed on the first cell stack region Cell ST1.

According to some example embodiments, the through via THV shown in FIG. 4A may be formed to extend into the first cell stack region Cell ST1 during the process of forming the first common source region CSL1. For example, the through via THV shown in FIG. 4A may be formed to penetrate through a portion of the source wiring insulation layer IMD-C and the interlayer insulation layer ILD. According to some other example embodiments, a portion of the through via THV shown in FIG. 4A may be formed during the process of forming the first cell stack region Cell ST1 and another portion of the through via THV may be formed during the process of forming the first common source region CSL1.

Referring to FIG. 5D, a carrier substrate CWF is attached onto the first common source region CSL1. The carrier substrate CWF may be, but is not limited to, a semiconductor substrate. According to some example embodiments, the carrier substrate CWF may be a bulk wafer.

Referring to FIGS. 5E and 5F together, a result structure of FIG. 5D is turned upside down such that the carrier substrate CWF faces downward and a first base substrate region BSUB1 faces upward, and then the first base substrate region BSUB1 is removed to expose the first cell stack region Cell ST1 upward.

Referring to FIG. 5G, the first bit line region BLR1 and the upper peripheral bonding region BPLC are sequentially formed on the first cell stack region Cell ST1. For example, the first bit line region BLR1 including the stud STD, the bit line contact BLC, the bit line BL, the bit line interconnect structure ITCS-B, the connection wiring layer SPD-B, and the bit line wiring insulation layer IMD-B surrounding the stud STD, the bit line contact BLC, the bit line BL, the bit line interconnect structure ITCS-B, and the connection wiring layer SPD-B may be formed on the first cell stack region Cell ST1, and the upper peripheral bonding region BPLC including the upper peripheral bonding contact BPC-B, the upper peripheral bonding pad BPD-B, and the upper peripheral insulation layer BDL-B surrounding the upper peripheral bonding contact BPC-B and the upper peripheral bonding pad BPD-B may be formed on the first bit line region BLR1.

The first bit line region BLR1 and the upper peripheral bonding region BPLC formed on the first cell stack region Cell ST1 may be formed such that they are upside down compared to the first bit line region BLR1 and the upper peripheral bonding region BPLC of FIG. 4A.

Referring to FIG. 5H, the peripheral circuit region Peri. and a lower peripheral bonding region BPLP are sequentially formed on the substrate region SUB. The substrate region SUB may be the substrate region SUB shown in FIG. 4A. The peripheral circuit region Peri. including the plurality of peripheral circuit transistors P-TR, the plurality of peripheral circuit contacts ITCS-P, the plurality of peripheral circuit wiring layers SPD-P as shown in FIG. 4A on the substrate region SUB, and the peripheral circuit insulation structure ILD-P covering the plurality of peripheral circuit transistors P-TR and surrounding the plurality of peripheral circuit contacts ITCS-P and the plurality of peripheral circuit wiring layers SPD-P may be formed. The lower peripheral bonding region BPLP including the lower peripheral bonding contact BPC-P, the lower peripheral bonding pad BPD-P, and the lower peripheral insulation layer BDL-P surrounding the lower peripheral bonding contact BPC-P and the lower peripheral bonding pad BPD-P as shown in FIG. 4A may be formed on the peripheral circuit region Peri.

Referring to FIG. 5I, a result structure of FIG. 5G is turned upside down and attached onto a result structure of FIG. 5H. The lower peripheral bonding region BPLP and the upper peripheral bonding region BPLC may face each other, and the carrier substrate CWF may be exposed. The lower peripheral bonding region BPLP and the upper peripheral bonding region BPLC may be bonded to each other through a hybrid bonding.

Referring to FIGS. 5J and 5K together, after the carrier substrate CWF is removed to expose the first common source region CSL1, the lower cell bonding region BPU1 is formed on the first common source region CSL1. The lower cell bonding region BPU1 including the cell bonding contact BPC-C, the cell bonding pad BPD-C, and the cell insulation layer BDL-C surrounding the cell bonding contact BPC-C and the cell bonding pad BPD-C may be formed on the first common source region CSL1.

Referring to FIG. 5L, the second cell stack region Cell ST2 is formed on a second base substrate region BSUB2, and the second common source region CSL2 is formed on the second cell stack region Cell ST2. For example, the second cell stack region Cell ST2 including the plurality of gate electrodes CDL, the interlayer insulation layer ILD, and the plurality of cell channel structures CHS as shown in FIG. 4A may be formed on the second base substrate region BSUB2, and the second common source region CSL2 including the common source line layer CSL, the source wiring insulation layer IMD-C, the gate contact plug CMC, the internal interconnect structure ITCS-I, and the internal wiring layer SPD-C as shown in FIG. 4A may be formed on the second cell stack region Cell ST2.

The second cell stack region Cell ST2 and the second common source region CSL2 formed on the second base substrate region BSUB2 may be formed to be upside down as compared to the second cell stack region Cell ST2 and the second common source region CSL2 of FIG. 4A.

According to some example embodiments, the through via THV shown in FIG. 4A may be formed to extend into the second cell stack region Cell ST2 during the process of forming the second common source region CSL2. For example, the through via THV shown in FIG. 4A may be formed to penetrate through a portion of the source wiring insulation layer IMD-C and the interlayer insulation layer ILD. According to some other example embodiments, a portion of the through via THV shown in FIG. 4A may be formed during the process of forming the second cell stack region Cell ST2 and another portion of the through via THV may be formed during the process of forming the second common source region CSL2.

Referring to FIG. 5M, the upper cell bonding region BPU2 is formed on the second common source region CSL2. The upper cell bonding region BPU2 including the cell bonding contact BPC-C, the cell bonding pad BPD-C, and the cell insulation layer BDL-C surrounding the cell bonding contact BPC-C and the cell bonding pad BPD-C may be formed on the second common source region CSL2. The upper cell bonding region BPU2 formed on the second common source region CSL2 may be formed to be upside down as compared to the upper cell bonding region BPU2 of FIG. 4A.

Referring to FIG. 5N, a result structure of FIG. 5M is turned upside down and attached onto a result structure of FIG. 5K. The lower cell bonding region BPU1 and the upper cell bonding region BPU2 may face each other, and the second base substrate region BSUB2 may be exposed. The lower cell bonding region BPU1 and the upper cell bonding region BPU2 may be bonded to each other through a hybrid bonding.

Referring to FIGS. 5O and 5P together, the second base substrate region BSUB2 is removed to expose the second cell stack region Cell ST2, and then the second bit line region BLR2 and the input/output region I/O may be formed on the second cell stack region Cell ST2, thereby forming the non-volatile memory device 10. For example, the second bit line region BLR2 including the stud STD, the bit line contact BLC, the bit line BL, the bit line interconnect structure ITCS-B, the connection wiring layer SPD-B, and the bit line wiring insulation layer IMD-B surrounding the stud STD, the bit line contact BLC, the bit line BL, the bit line interconnect structure ITCS-B, and the connection wiring layer SPD-B may be formed on the second cell stack region Cell ST2, and the input/output region I/O including the input/output contact PDC, the input/output pad PAD, and the input/output insulation layer IOD surrounding the input/output contact PDC and the input/output pad PAD may be formed on the second bit line region BLR2.

FIGS. 6A to 6N are cross-sectional views showing a method of manufacturing a non-volatile memory device, according to an example embodiment. In detail, FIGS. 6A to 6N are enlarged cross-sectional views of a portion corresponding to the portion ENB of FIG. 4A, and FIGS. 6A to 6L are shown upside down as compared to the portion ENB of FIG. 4A.

Referring to FIG. 6A, the first base substrate region BSUB1 is prepared. According to some example embodiments, the first base substrate region BSUB1 may be a bulk wafer.

Referring to FIG. 6B, a preliminary insulation layer PILD covering the first base substrate region BSUB1 is formed. The preliminary insulation layer PILD may include an insulation material. According to some example embodiments, the preliminary insulation layer PILD may include the same material as the interlayer insulation layer ILD shown in FIG. 4A, but the inventive concepts are not limited thereto.

Referring to FIG. 6C, a portion of the preliminary insulation layer PILD and an upper portion of the first base substrate region BSUB1 are removed to form the base opening BOP extending from the uppermost portion of the preliminary insulation layer PILD into the interior of the first base substrate region BSUB1. The base opening BOP may be formed to penetrate through the preliminary insulation layer PILD, may extend from the top surface of the first base substrate region BSUB1 into the first base substrate region BSUB1, and may not penetrate through the first base substrate region BSUB1. According to some example embodiments, the base opening BOP may be formed to have a generally equal horizontal width in the vertical direction. The base opening BOP may have a horizontal cross-section having a circular shape or a ring-like shape.

Referring to FIG. 6D, a main spacer layer MSPC covering a surface of the preliminary insulation layer PILD and a surface of the first base substrate region BSUB1 that are exposed to the inner wall (e.g., the boundary) of the base opening BOP is formed. For example, the main spacer layer MSPC may include nitride.

Referring to FIG. 6E, a portion of the first base substrate region BSUB1is removed from the bottom surface or the bottom of the base opening BOP by using the preliminary insulation layer PILD and the main spacer layer MSPC as etching masks to form an extended opening EOP communicating with the base opening BOP. The horizontal width of the extended opening EOP may be smaller than the horizontal width of the base opening BOP due to the main spacer layer MSPC.

Referring to FIGS. 6E and 6F together, after the main spacer layer MSPC is removed, an etch stop sacrificial film STB filling the base opening BOP and the extended opening EOP is formed. The etch stop sacrificial film STB may include a material having an etch selectivity with respect to each of the plurality of interlayer insulation layers ILD, a plurality of sacrificial films STL, and the first base substrate region BSUB1 to be formed in FIG. 6G. According to some embodiments, the etch stop sacrificial film STB may include a material containing carbon.

Referring to FIG. 6G, the plurality of interlayer insulation layers ILD and the plurality of sacrificial films STL are alternately formed on the first base substrate region BSUB1 and the etch stop sacrificial film STB. The plurality of interlayer insulation layers ILD and the plurality of sacrificial films STL may include materials having different etch selectivity. According to some example embodiments, each of the plurality of interlayer insulation layers ILD may include an oxide, and the plurality of sacrificial films STL may include a nitride, but the inventive concepts are not limited thereto.

According to some example embodiments, the lowermost interlayer insulation layer ILD from among the plurality of interlayer insulation layers ILD may be formed by forming an insulation material layer on the preliminary insulation layer PILD and the etch stop sacrificial film STB such that the lowermost interlayer insulation layer ILD includes the preliminary insulation layer PILD and the insulation material layer. According to some example embodiments, the lowermost interlayer insulation layer ILD from among the plurality of interlayer insulation layers ILD may be formed to cover the first base substrate region BSUB1 and the etch stop sacrificial film STB after the preliminary insulation layer PILD is removed.

Referring to FIG. 6H, the channel hole CHH penetrating through the plurality of interlayer insulation layers ILD and the plurality of sacrificial films STL is formed. The channel hole CHH may be formed by removing a portion of each of the plurality of interlayer insulation layers ILD and a portion of each of the plurality of sacrificial films STL to expose the etch stop sacrificial film STB. In the process of forming the channel hole CHH, a portion of the etch stop sacrificial film STB embedded in the lowest interlayer insulation layer ILD from among the plurality of interlayer insulation layers ILD may be removed together, but the inventive concepts are not limited thereto. For example, in the process of forming the channel hole CHH, the etch stop sacrificial film STB may be maintained without being removed.

The horizontal width of the channel hole CHH may be smaller than the horizontal width of the base opening BOP. The horizontal width of the channel hole CHH may be equal to or greater than the horizontal width of the extended opening EOP.

Referring to FIGS. 6H and 6I together, the etch stop sacrificial film STB may be removed such that the channel hole CHH extends to the base opening BOP and the extended opening EOP. The first base substrate region BSUB1 may be exposed on the bottom surface of the channel hole CHH including the base opening BOP and the extended opening EOP.

Referring to FIG. 6J, the gate insulation layer GDI, which covers the inner surfaces (e.g., the inner side surface and the bottom surface) of the channel hole CHH including the base opening BOP and the extended opening EOP, and a pad material layer PBLP are formed. The gate insulation layer GDI may be formed to conformally cover surfaces of the plurality of interlayer insulation layers ILD, the plurality of sacrificial films STL, and the first base substrate region BSUB1 exposed on the inner surface (e.g., the boundary) of the channel hole CHH including the base opening BOP and an extended opening EOP. A pad material layer PBLP may conformally cover the gate insulation layer GDI within the channel hole CHH including the base opening BOP and the extended opening EOP such that the pad material layer PBLP fills the extended opening EOP. The pad material layer PBLP may be formed to completely fill the extended opening EOP, but only to partially fill the remaining portion of the channel hole CHH (e.g., a portion of the channel hole CHH excluding the extended opening EOP). For example, the pad material layer PBLP may be formed to fill only a portion of the channel hole CHH that penetrates through the plurality of interlayer insulation layers ILD, the plurality of sacrificial films STL and a portion of the base opening BOP, and leave the remaining portion unfilled. The pad material layer PBLP may include conductive polysilicon. For example, the pad material layer PBLP may include n+polysilicon that is heavily doped with n-type impurities to provide conductivity.

Referring to FIGS. 6J and 6K together, a portion of the pad material layer PBLP is removed to form the bit line pad BLP. The bit line pad BLP may be formed to fill at least a portion of the extended opening EOP. For example, the bit line pad BLP may be formed to fill at least a lower portion of the extended opening EOP, but may not be formed in portions of the channel hole CHH, which penetrate through the plurality of interlayer insulation layers ILD and the plurality of sacrificial films STL, and the base opening BOP.

After forming the bit line pad BLP, the channel layer CHL and the buried insulation layer BIL are formed, thereby forming the cell channel structure CHS including the gate insulation layer GDI, the bit line pad BLP, the channel layer CHL, and the buried insulation layer BIL. The channel layer CHL may be formed to conformally cover the gate insulation layer GDI and the bit line pad BLP within the channel hole CHH, and the buried insulation layer BIL may be formed to entirely fill the channel hole CHH.

Referring to FIGS. 6K and 6L together, after removing the plurality of sacrificial films STL, the plurality of gate electrodes CDL are formed to fill the space from which the plurality of sacrificial films STL have been removed. The plurality of gate electrodes CDL and the plurality of interlayer insulation layers ILD that are alternately arranged may form the cell stack CST.

Referring to FIGS. 6M and 6N together, a result structure of FIG. 6L is turned upside down, such that the first base substrate region BSUB1 is facing upward. The first base substrate region BSUB1 is removed to expose the gate insulation layer GDI.

Thereafter, as shown in FIG. 4B, the stud STD connected to the bit line pad BLP, the bit line contact BLC connected to the stud STD, the bit line BL connected to the bit line contact BLC, and the bit line wiring insulation layer IMD-B surrounding the gate insulation layer GDI, the stud STD, the bit line contact BLC, and the bit line BL may be formed through the gate insulation layer GDI.

Because the stud STD is formed to penetrate through the gate insulation layer GDI and be connected to the bit line pad BLP, a portion of the side surface of the stud STD adjacent to the bit line pad BLP may be covered by the insulation extension CDIB.

Referring to FIGS. 4A to 4C, 5A to 5P, and 6A to 6N together, in the non-volatile memory device 10 according to some example embodiments, the pad material layer PBLP is formed within the base opening BOP having a horizontal width greater than the horizontal width of a portion of the channel hole CHH penetrating through the plurality of interlayer insulation layers ILD and the plurality of sacrificial films STL and within the extended opening EOP having a horizontal width smaller than the horizontal width of the base opening BOP, and then a portion of the pad material layer PBLP is removed to form the bit line pad BLP within the extended opening EOP having a relatively narrow horizontal width. Therefore, the dispersion of shapes of bit line pads BLP included in the plurality of cell channel structures CHS may be reduced, and the connection reliability between the channel layer CHL and the bit line BL may be improved, thereby implementing the non-volatile memory device 10 having improved operational reliability.

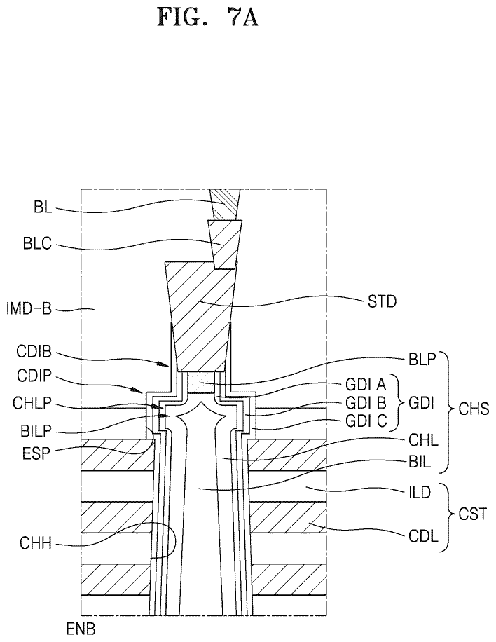

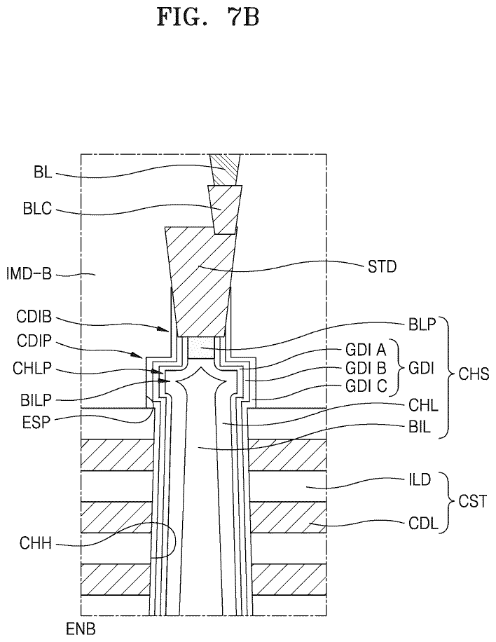

FIGS. 7A and 7B are cross-sectional views of a non-volatile memory device according to some example embodiments. In detail, FIG. 7A is an enlarged cross-sectional view of a portion corresponding to the portion ENB of FIG. 4A, according to one example embodiment, and FIG. 7B is an enlarged cross-sectional view of a portion corresponding to the portion ENB of FIG. 4A, according to another example embodiment.

Referring to FIG. 7A, the expanded space ESP of the channel hole CHH may be in contact with the gate electrode CDL most adjacent to the bit line BL from among the plurality of gate electrodes CDL. A portion of the surface of the gate electrode CDL, which is closest to the bit line BL from among the plurality of gate electrodes CDL, facing the bit line BL (e.g., a portion of the bottom surface of the lowermost gate electrode CDL from among the plurality of gate electrodes CDL in the first cell stack region Cell ST1 or a portion of the top surface of the uppermost gate electrode CDL from among the plurality of gate electrodes CDL in the second cell stack region Cell ST2 shown in FIG. 4A) may be in contact with the gate insulation layer GDI.

The lowermost gate electrode CDL from among the plurality of gate electrodes CDL in the first cell stack region Cell ST1 and the uppermost gate electrode CDL from among the plurality of gate electrodes CDL in the second cell stack region Cell ST2 shown in FIG. 4A may each be the string select line SSL. Therefore, the operating characteristics of the string select transistor SST shown in FIG. 3 may be controlled differently from the operating characteristics of the ground select transistor GST and/or the operating characteristics of the plurality of memory cell transistors MC1, MC2, . . . , MCn−1, and MCn.

Referring to FIG. 7B, the expanded space ESP of the channel hole CHH may be separated from the plurality of gate electrodes CDL. The interlayer insulation layer ILD may be disposed between the gate electrode CDL most adjacent to the bit line BL from among the plurality of gate electrodes CDL and the expanded space ESP of the channel hole CHH. The expanded space ESP may be located only within the bit line wiring insulation layer IMD-B and not within the cell stack CST. For example, the expanded space ESP may be located within a portion of the bit line wiring insulation layer IMD-B that contacts the cell stack CST.

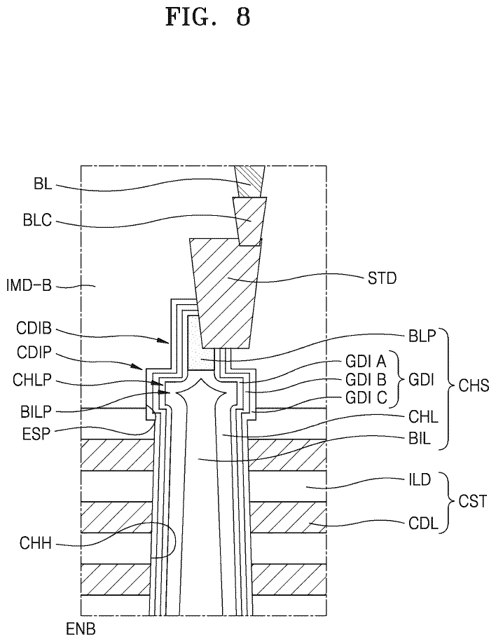

FIG. 8 is a cross-sectional view of a non-volatile memory device according to an example embodiment. In detail, FIG. 8 is an enlarged cross-sectional view of a portion corresponding to the portion ENB of FIG. 4A.

Referring to FIG. 8, the bit line pad BLP and the stud STD may not be aligned in the vertical direction and may be misaligned. For example, the stud STD may be shifted from the bit line pad BLP in a horizontal direction. For example, the bit line pad BLP may contact a portion of the bottom surface of the stud STD and a portion of the side surface of the stud STD.

Therefore, when forming the stud STD connected to the bit line pad BLP, even when a misalignment occurs between the bit line pad BLP and the stud STD and the lower portion of the stud STD in contact with the bit line pad BLP is reduced, a portion of the side surface of the stud STD contacts the bit line pad BLP, and thus the connection reliability between the channel layer CHL and the bit line BL may be improved.

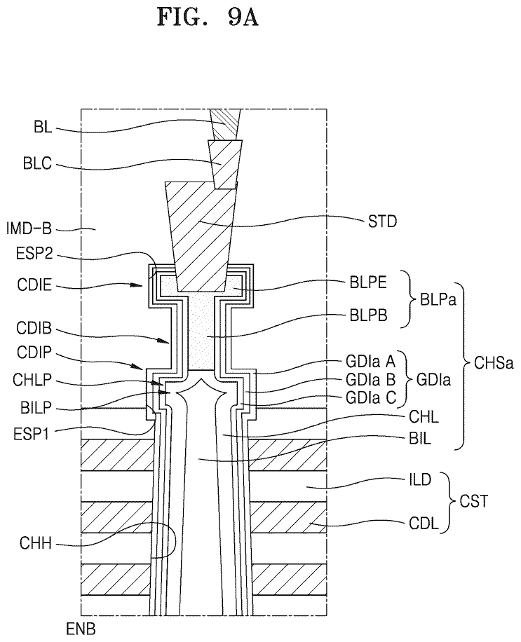

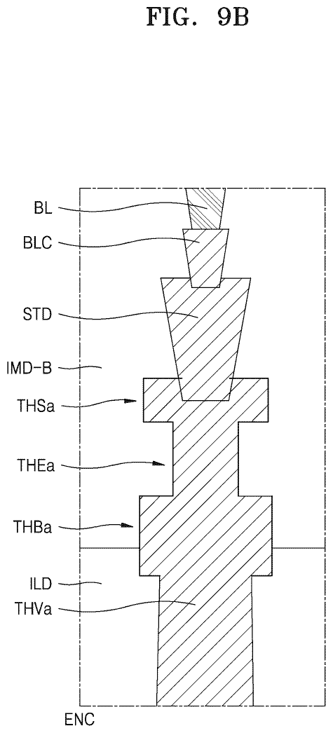

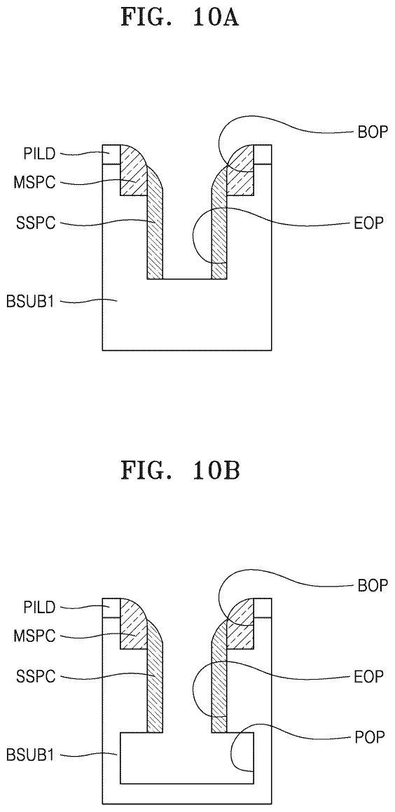

FIGS. 9A and 9B are cross-sectional views of a non-volatile memory device according to an example embodiment. In detail, FIG. 9A is an enlarged cross-sectional view of a portion corresponding to the portion ENB of FIG. 4A, and FIG. 9B is an enlarged cross-sectional view of a portion corresponding to the portion ENC of FIG. 4A.

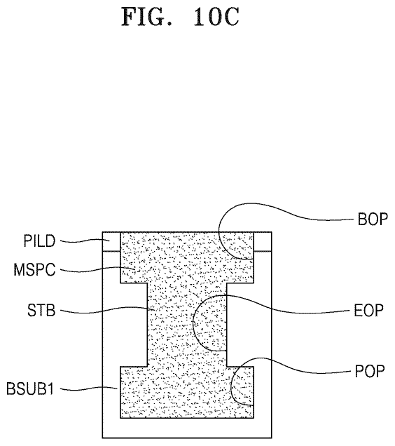

Referring to FIGS. 9A and 9B together, the channel hole CHH may include a first expanded space ESP1 corresponding to the base opening BOP shown in FIGS. 10A to 10C and a second expanded space ESP2 corresponding to an extended opening POP. The horizontal width of each of the first expanded space ESP1 and the second expanded space ESP2 may be greater than the horizontal width of the channel hole CHH. The first expanded space ESP1 of the channel hole CHH may be disposed across the cell stack CST and the bit line wiring insulation layer IMD-B, and the second expanded space ESP2 may be disposed within the bit line wiring insulation layer IMD-B. The first expanded space ESP1 is the same as or substantially similar to the expanded space ESP shown in FIG. 4B, FIG. 7A, or FIG. 7B, and thus descriptions identical to those given above are omitted.

A cell channel structure CHSa may include a gate insulation layer GDIa, the channel layer CHL, the buried insulation layer BIL, and a bit line pad BLPa. The gate insulation layer GDIa may have a structure including a tunneling dielectric film GDIaA, a charge storage film GDIaB, and a blocking dielectric film GDIaC. The gate insulation layer GDIa may include a body portion of the gate insulation layer GDIa, the insulation protrusion CDIP, the insulation extension CDIB, and an insulation extension CDIE. The insulation protrusion CDIP and the insulation extension CDIE may be referred to as a first insulation protrusion and a second insulation protrusion, respectively. The insulation extension CDIB and the insulation extension CDIE may surround the bit line pad BLPa.

The bit line pad BLPa may have a T-shaped vertical cross-section including a pad extension BLPB that fills a portion of the extended opening EOP and a pad expansion BLPE that fills the extended opening POP as shown in FIGS. 10B and 10C. The pad expansion BLPE may protrude in a horizontal direction further than the pad extension BLPB and have a wider horizontal width than the pad extension BLPB. The insulation extension CDIB may surround the pad extension BLPB, and the insulation extension CDIE may surround the pad expansion BLPE. The stud STD may be connected to the pad expansion BLPE of the bit line pad BLPa, and the channel layer CHL may be connected to the pad extension BLPB of the bit line pad BLPa.

A through via THVa may include a via protrusion THBa, a via extension THEa, and a via expansion THSa. The via protrusion THBa and the via expansion THSa may be referred to as a first via protrusion and a second via protrusion, respectively. The via expansion THSa may have a horizontal width greater than that of the via extension THEa. The via expansion THSa may be located at the same or substantially similar vertical level as the pad expansion BLPE. The stud STD may be connected to the via expansion THSa. Because the stud STD is connected to the pad expansion BLPE of the bit line pad BLPa or the via expansion THSa of the through via THVa having a relatively wide horizontal width, the connection reliability between the channel layer CHL and the bit line BL or between the through via THVa and the bit line BL may be improved.

FIGS. 10A to 10C are cross-sectional views showing a method of manufacturing a non-volatile memory device, according to an example embodiment. In detail, FIGS. 10A to 10C are enlarged cross-sectional views of a portion corresponding to the portion ENB of FIG. 4A, and FIGS. 10A to 10C are shown upside down as compared to the portion ENB of FIG. 4A.

Referring to FIG. 10A, after forming the extended opening EOP shown in FIG. 6E, a sub spacer layer SSPC is formed that covers the surface of the main spacer layer MSPC exposed within the base opening BOP and the surface of the first base substrate region BSUB1 exposed to the inner wall of the extended opening EOP. According to some example embodiments, the sub spacer layer SSPC may include a material having the same or similar etching characteristics as that of the main spacer layer MSPC.

Referring to FIG. 10B, a portion of the first base substrate region BSUB1 is removed from the bottom surface of the extended opening EOP through isotropic etching using the preliminary insulation layer PILD, the main spacer layer MSPC, and the sub spacer layer SSPC as etching masks, thereby forming the extended opening POP connected to the extended opening EOP. Because the extended opening POP is formed through isotropic etching, the horizontal width of the extended opening POP may be wider than the horizontal width of the extended opening EOP. The extended opening POP may have a horizontal cross-section of a circular shape or a ring-like shape.

Referring to FIGS. 10B and 10C together, after the main spacer layer MSPC and the sub spacer layer SSPC are removed, the etch stop sacrificial film STB is formed to fill the base opening BOP, the extended opening EOP, and the extended opening POP. Thereafter, subsequent operations are performed with reference to FIGS. 6G to 6N.

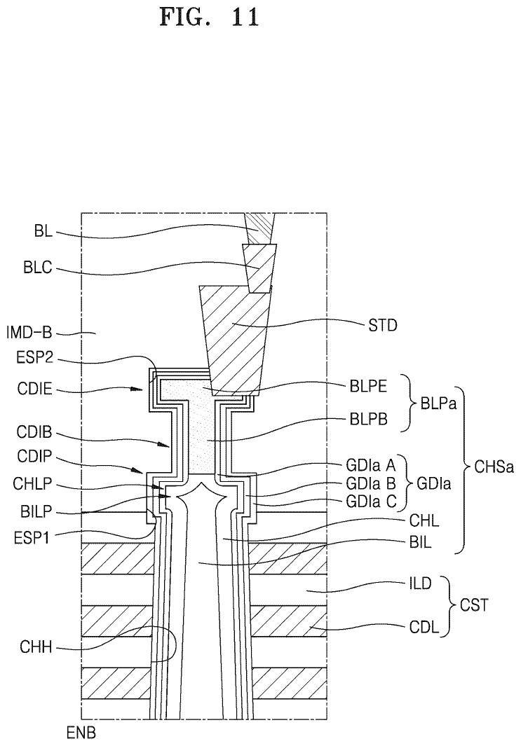

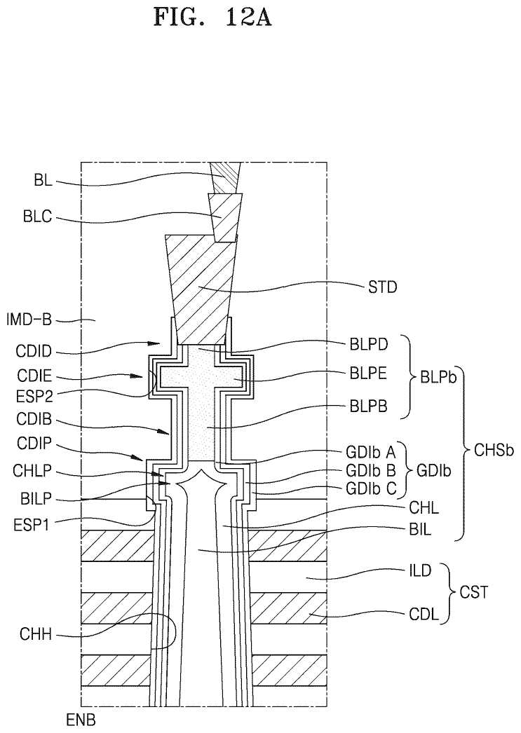

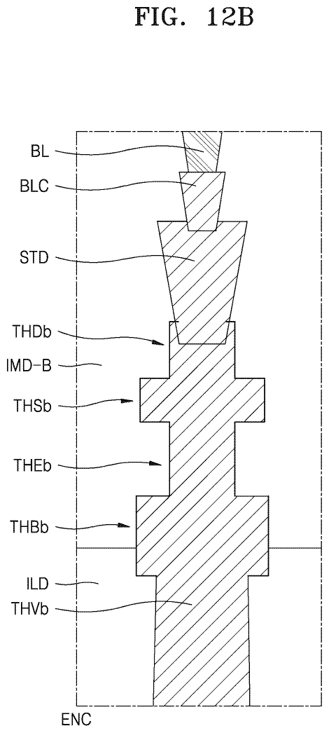

FIG. 11 is a cross-sectional view of a non-volatile memory device according to an example embodiment. In detail, FIG. 11 is an enlarged cross-sectional view of a portion corresponding to the portion ENB of FIG. 4A.

Referring to FIG. 11, the bit line pad BLPa and the stud STD may not be aligned in the vertical direction and may be misaligned. For example, the stud STD may be shifted from the bit line pad BLPa in a horizontal direction. When forming the stud STD connected to the bit line pad BLPa, even when misalignment occurs between the bit line pad BLPa and the stud STD, because the bit line pad BLPa includes the pad expansion BLPE and the stud STD is connected to the pad expansion BLPE having a relatively wide horizontal width, the connection reliability between the channel layer CHL and the bit line BL may be improved.

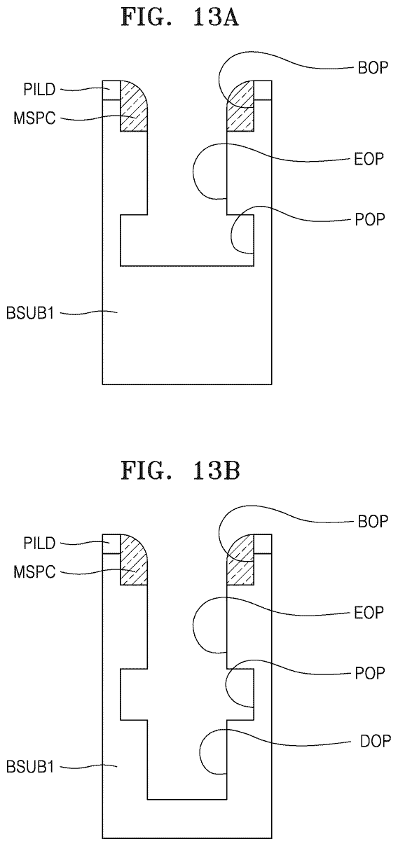

FIGS. 12A and 12B are cross-sectional views of a non-volatile memory device according to an example embodiment. In detail, FIG. 12A is an enlarged cross-sectional view of a portion corresponding to the portion ENB of FIG. 4A, and FIG. 12B is an enlarged cross-sectional view of a portion corresponding to the portion ENC of FIG. 4A.

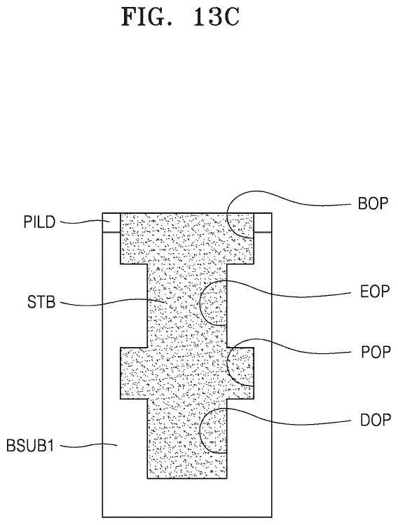

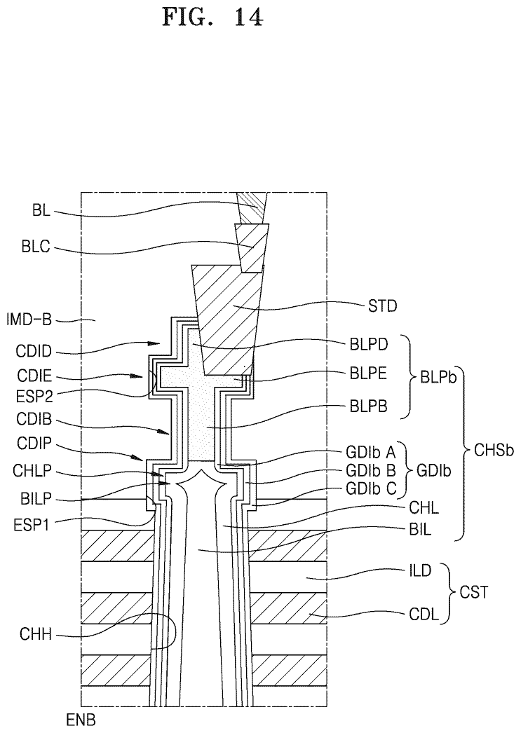

Referring to FIGS. 12A and 12B together, the channel hole CHH may include the first expanded space ESP1 and the second expanded space ESP2 corresponding to the extended opening POP corresponding to the base opening BOP shown in FIGS. 13A to 13C and may further extend from the second expanded space ESP2 toward the bit line BL in correspondence to a deep extended opening DOP. The horizontal width of each of the first expanded space ESP1 and the second expanded space ESP2 may be greater than the horizontal width of another portion of the channel hole CHH.

A cell channel structure CHSb may include a gate insulation layer GDIb, the channel layer CHL, the buried insulation layer BIL, and a bit line pad BLPb. The gate insulation layer GDIb may have a structure including a tunneling dielectric film GDIbA, a charge storage film GDIbB, and a blocking dielectric film GDIbC. The gate insulation layer GDIb may include a body portion of the gate insulation layer GDIb, the insulation protrusion CDIP, the insulation extension CDIB, the insulation extension CDIE, and an insulation deep extension CDID. The insulation protrusion CDIP and the insulation extension CDIE may be referred to as a first insulation protrusion and a second insulation protrusion, respectively, and the insulation extension CDIB and the insulation deep extension CDID may be referred to as a first insulation extension and a second insulation extension, respectively. The insulation extension CDIB, the insulation extension CDIE, and the insulation deep extension CDID may surround the bit line pad BLPb.

The bit line pad BLPb may have a T-shaped vertical cross-section including a pad extension BLPB that fills a portion of the extended opening EOP, a pad expansion BLPE that fills the extended opening POP, and a pad deep extension BLPD that fills the deep extended opening DOP as shown in FIGS. 13B and 13C. The pad extension BLPB and the pad deep extension BLPD may be referred to as a first pad extension and a second pad extension. respectively. The pad expansion BLPE may protrude in a horizontal direction further than each of the pad extension BLPB and the pad deep extension BLPD and may have a horizontal width wider than that of each of the pad extension BLPB and the pad deep extension BLPD. The insulation extension CDIB may surround the pad extension BLPB, the insulation extension CDIE may surround the pad expansion BLPE, and the insulation deep extension CDID may surround the pad deep extension BLPD. The channel layer CHL may be connected to the pad extension BLPB of the bit line pad BLPb, and the stud STD may be connected to the pad deep extension BLPD of the bit line pad BLPb or may be connected to the pad expansion BLPE and the pad deep extension BLPD.

A through via THVb may include a via protrusion THBb, a via extension THEb, a via expansion THSdb, and a via deep extension THDb. The via protrusion THBb and the via expansion THSdb may be referred to as a first via protrusion and a second via protrusion, respectively, and the via extension THEb and the via deep extension THDb may be referred to as a first via extension and a second via extension, respectively. The via expansion THSdb and the via protrusion THBb may have horizontal widths wider than those of the via extension THEb and the via deep extension THDb. The via deep extension THDb may be located at the same or substantially similar vertical level as the pad deep extension BLPD. the stud STD may be connected to the via deep extension THDb.

FIGS. 13A to 13C are cross-sectional views showing a method of manufacturing a non-volatile memory device, according to an example embodiment. In detail, FIGS. 13A to 13C are enlarged cross-sectional views of a portion corresponding to the portion ENB of FIG. 4A, and FIGS. 13A to 13C are shown upside down as compared to the portion ENB of FIG. 4A.

Referring to FIG. 13A, after forming the extended opening POP shown in FIG. 10B, the sub spacer layer SSPC is removed. For example, the sub spacer layer SSPC may include a material having different etching characteristics from the main spacer layer MSPC.

Referring to FIG. 13B, a portion of the first base substrate region BSUB1 is removed from the bottom surface (e.g., the bottom) of the extended opening POP through anisotropic etching using the preliminary insulation layer PILD and the main spacer layer MSPC as etching masks to form the deep extended opening DOP communicating with the extended opening POP. Because the deep extended opening DOP is formed through anisotropic etching, the horizontal width of the deep extended opening DOP may be smaller than the horizontal width of the extended opening POP and the same as or substantially similar to the horizontal width of the extended opening EOP.

Referring to FIG. 13C, after removing the main spacer layer MSPC, the etch stop sacrificial film STB that fills the base opening BOP, the extended opening EOP, the extended opening POP, and the deep extended opening DOP is formed. Thereafter, subsequent operations are performed with reference to FIGS. 6G to 6N.

FIG. 14 is a cross-sectional view of a non-volatile memory device according to an example embodiment. In detail, FIG. 14 is an enlarged cross-sectional view of a portion corresponding to the portion ENB of FIG. 4A.

Referring to FIG. 14, the bit line pad BLPb and the stud STD may not be aligned in the vertical direction and may be misaligned. For example, the stud STD may be shifted from the bit line pad BLPb in a horizontal direction. For example, the bit line pad BLPb may contact at least portion of the bottom surface of the stud STD and a portion of the side surface of the stud STD. For example, the stud STD may be connected to the pad expansion BLPE and the pad deep extension BLPD of the bit line pad BLPb.

Therefore, when forming the stud STD connected to the bit line pad BLPb, even when misalignment occurs between the bit line pad BLPb and the stud STD, the reduction of a portion of the bottom surface of the stud STD in contact with the bit line pad BLPb is reduced or minimized by the pad expansion BLPE, and a portion of the side surface of the stud STD in contact with the bit line pad BLPb is formed by the pad deep extension BLPD, and thus the connection reliability between the channel layer CHL and the bit line BL may be improved.

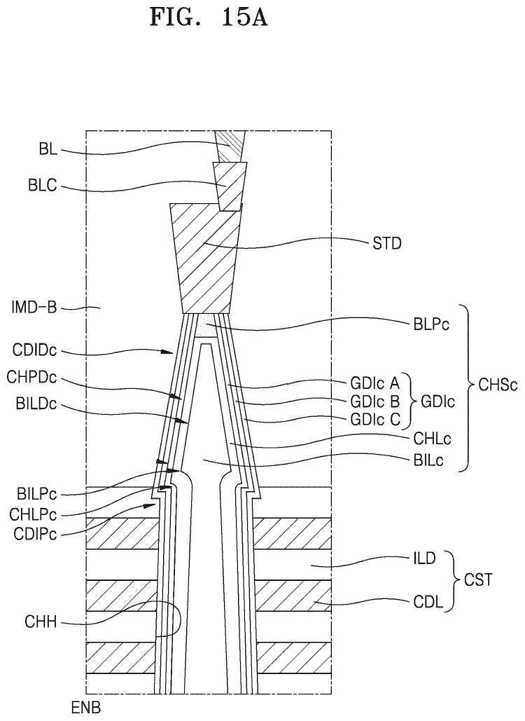

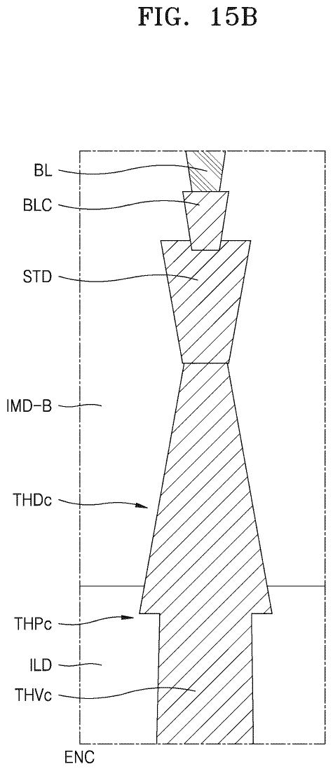

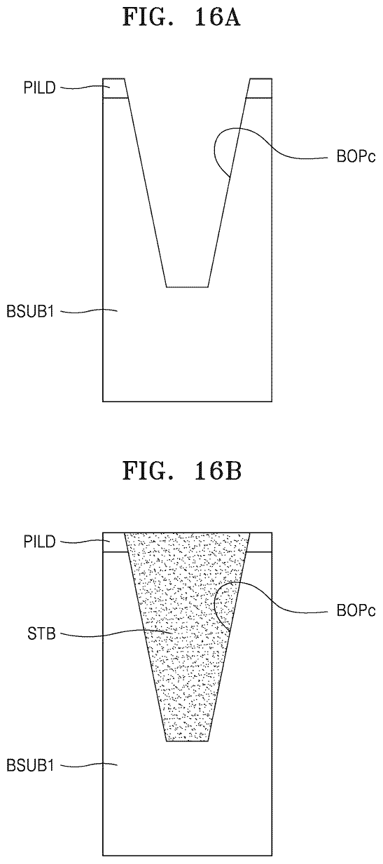

FIGS. 15A and 15B are cross-sectional views of a non-volatile memory device according to an example embodiment. In detail, FIG. 15A is an enlarged cross-sectional view of a portion corresponding to the portion ENB of FIG. 4A, and FIG. 15B is an enlarged cross-sectional view of a portion corresponding to the portion ENC of FIG. 4A.

Referring to FIGS. 15A and 15B together, the channel hole CHH may have an expanded space corresponding to an extended opening BOPc shown in FIGS. 16A and 16B. The maximum horizontal width of the above-stated expanded space of the channel hole CHH may be greater than the horizontal width of other portions of the channel hole CHH, and the minimum horizontal width of the above-stated expanded space of the channel hole CHH may be smaller than the other parts of the channel hole CHH. The expanded space of the channel hole CHH may be disposed across the cell stack CST and the bit line wiring insulation layer IMD-B. The expanded space of the channel hole CHH may have a tapered shape having the horizontal width decreasing toward the bit line BL. A portion of a cell channel structure CHS extending from one end of the cell stack CST toward the bit line BL from among the cell channel structures CHS (e.g., a portion of the cell channel structure CHS filling the expanded space of the channel hole CHH) may have a tapered shape of which the horizontal width decreases toward the bit line BL.

A cell channel structure CHSc may include a gate insulation layer GDIc, a channel layer CHLc, a buried insulation layer BILc, and a bit line pad BLPc. The gate insulation layer GDIc may have a structure including a tunneling dielectric film GDIcA, a charge storage film GDIcB, and a blocking dielectric film GDIcC. The gate insulation layer GDIc may include a body portion of a gate insulation layer GDIc, an insulation protrusion CDIPc, and an insulation extension CDIDc. The buried insulation layer BILc may include a body portion of the buried insulation layer BILc, a buried protrusion BILPc, and a buried extension BILDc. The channel layer CHLc may include a body portion of the channel layer CHLc, a channel protrusion CHLPc, and a channel extension CHPDc. The channel extension CHPDc may surround the buried extension BILDc, and the insulation extension CDIDc may surround around the side surface of the channel extension CHPDc and the side surface of the bit line pad BLPc. The channel extension CHPDc may be connected to the bit line pad BLPc. The buried extension BILDc may have a tapered shape of which the horizontal width decreases from a buried protrusion BILPc toward the bit line BL. The bit line pad BLPc may have a tapered shape of which the horizontal width decreases from the channel layer CHLc toward the bit line BL. The insulation protrusion CDIPc may protrude from a body portion of the gate insulation layer GDIc in a horizontal direction, the buried protrusion BILPc may protrude from a body portion of the buried insulation layer BILc in a horizontal direction, and the channel protrusion CHLPc may protrude from a body portion of the channel layer CHLc in a horizontal direction.

A through via THVc may include a via protrusion THPc and a via extension THDc. The via protrusion THPc may protrude in a horizontal direction from a body portion of the through via THVc. The via extension THDc may have a tapered shape having the horizontal width that decreases toward the bit line BL.

FIGS. 16A and 16B are cross-sectional views showing a method of manufacturing a non-volatile memory device, according to an example embodiment. In detail, FIGS. 16A and 16B are enlarged cross-sectional views of a portion corresponding to the portion ENB of FIG. 4A, and FIGS. 16A and 16B are shown upside down as compared to the portion ENB of FIG. 4A.

Referring to FIG. 16A, after forming the preliminary insulation layer PILD shown in FIG. 6B, an upper portion of the first base substrate region BSUB1 is removed through the preliminary insulation layer PILD, thereby forming a base opening BOPc extending from the uppermost portion of the preliminary insulation layer PILD into the first base substrate region BSUB1. The base opening BOPc may be formed to penetrate through the preliminary insulation layer PILD, may extend from the top surface of the first base substrate region BSUB1 into the first base substrate region BSUB1, and may not penetrate through the first base substrate region BSUB1. According to some example embodiments, the base opening BOPc may be formed to have a tapered shape with the horizontal width that decreases from the preliminary insulation layer PILD toward the interior of the first base substrate region BSUB1. For example, the base opening BOPc may be formed by supplying relatively little etchant into the interior of the first base substrate region BSUB1.

Referring to FIG. 16B, the etch stop sacrificial film STB is formed to fill the base opening BOPc. Thereafter, subsequent operations are performed with reference to FIGS. 6G to 6N.

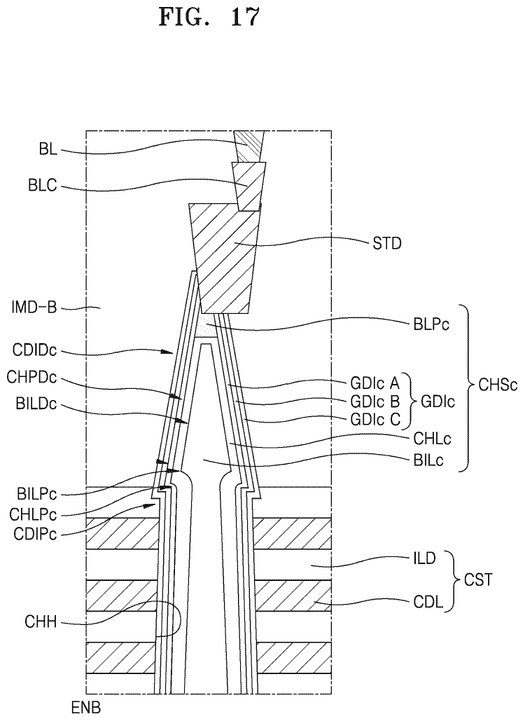

FIG. 17 is a cross-sectional view of a non-volatile memory device according to an example embodiment. In detail, FIG. 17 is an enlarged cross-sectional view of a portion corresponding to the portion ENB of FIG. 4A.

Referring to FIG. 17, the bit line pad BLPc and the stud STD may not be aligned in the vertical direction and may be misaligned. For example, the stud STD may be shifted from the bit line pad BLPc in a horizontal direction. For example, the bit line pad BLPc may contact at least portion of the bottom surface of the stud STD and a portion of the side surface of the stud STD. Therefore, when forming the stud STD connected to the bit line pad BLPc, even when a misalignment occurs between the bit line pad BLPc and the stud STD, the bit line pad BLPc contacts portions of the side surface and the bottom surface the stud STD, and thus the connection reliability between the channel layer CHLc and the bit line BL may be improved.

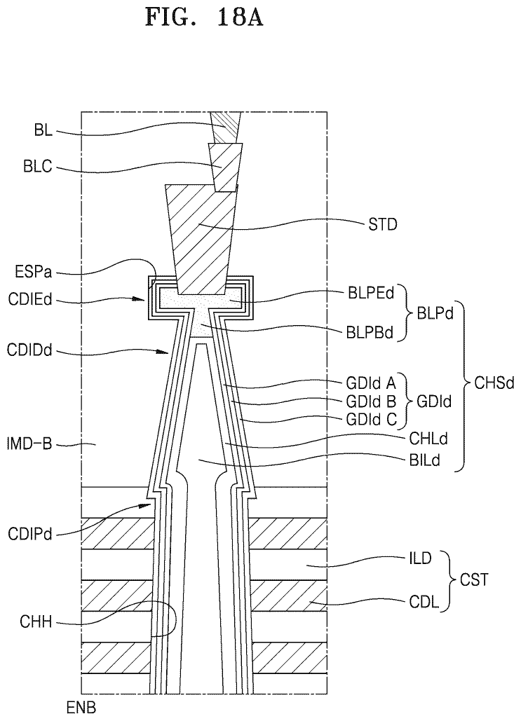

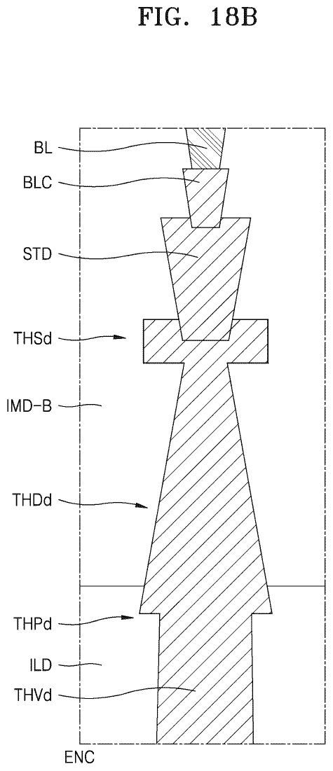

FIGS. 18A and 18B are cross-sectional views of a non-volatile memory device according to an example embodiment. In detail, FIG. 18A is an enlarged cross-sectional view of a portion corresponding to the portion ENB of FIG. 4A, and FIG. 18B is an enlarged cross-sectional view of a portion corresponding to the portion ENC of FIG. 4A.

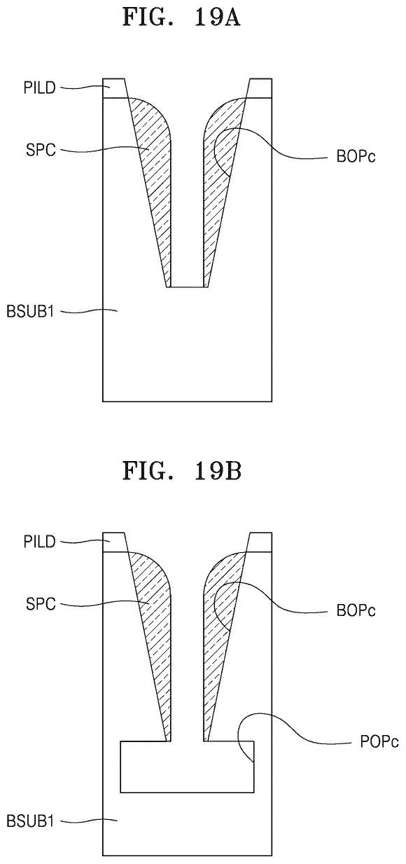

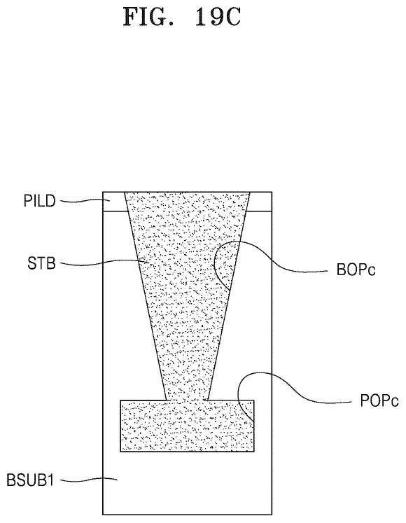

Referring to FIGS. 18A and 18B together, the channel hole CHH may have an expanded space corresponding to the extended opening BOPc shown in FIGS. 19A and 19B and an expanded space ESPa corresponding to an extended opening POPc. The maximum horizontal width of the above-stated expanded space of the channel hole CHH may be greater than the horizontal width of other portions of the channel hole CHH, and the minimum horizontal width of the above-stated expanded space of the channel hole CHH may be smaller than the other parts of the channel hole CHH. The horizontal width of the expanded space ESPa of the channel hole CHH may be greater than the minimum horizontal width of the expanded space of the channel hole CHH. The expanded space of the channel hole CHH may be disposed across the cell stack CST and the bit line wiring insulation layer IMD-B, and the expanded space ESPa may be disposed within the bit line wiring insulation layer IMD-B. The expanded space of the channel hole CHH may have a tapered shape having the horizontal width decreasing toward the bit line BL.

A cell channel structure CHSd may include a gate insulation layer GDId, a channel layer CHLd, a buried insulation layer BILd, and a bit line pad BLPd. The gate insulation layer GDId may have a structure including a tunneling dielectric film GDIdA, a charge storage film GDIdB, and a blocking dielectric film GDIdC. The gate insulation layer GDId may include a body portion of the gate insulation layer GDId, an insulation protrusion CDIPd, an insulation extension CDIDd, and an insulation extension CDIEd. The channel layer CHLd and the buried insulation layer BILd are generally the same as the channel layer CHLc and the buried insulation layer BILc shown in FIG. 15A, respectively, and thus descriptions identical to those given above are omitted. The insulation extension CDIDd and the insulation extension CDIEd may surround the bit line pad BLPd.

The bit line pad BLPd may have a T-shaped vertical cross-section including a pad extension BLPBd that fills a portion of the extended opening BOPc and a pad expansion BLPEd that fills the extended opening POPc as shown in FIGS. 19A to 19C. The pad expansion BLPEd may protrude in a horizontal direction further than the pad extension BLPBd and have a wider horizontal width than the pad extension BLPBd. The insulation extension CDIDd may surround the pad extension BLPBd, and the insulation extension CDIEd may surround the pad expansion BLPEd. The stud STD may be connected to the pad expansion BLPEd of the bit line pad BLPd.

A through via THVd may include a via protrusion THPd, a via extension THDd, and a via expansion THSd. The via protrusion THPd may protrude in a horizontal direction from a body portion of the through via THVd. The via extension THDd may have a tapered shape having the horizontal width that decreases toward the bit line BL. The via expansion THSd may be located at the same or substantially similar vertical level as the pad expansion BLPEd. The via expansion THSd may protrude in a horizontal direction further than the via extension THDd and have a wider horizontal width than the via extension THDd. The stud STD may be connected to the via expansion THSd. Because the stud STD is connected to the pad expansion BLPEd of the bit line pad BLPd or the via expansion THSd of the through via THVd having a relatively wide horizontal width, the connection reliability between the channel layer CHLd and the bit line BL or between the through via THVa and the bit line BL may be improved.

FIGS. 19A to 19C are cross-sectional views showing a method of manufacturing a non-volatile memory device, according to an example embodiment. In detail, FIGS. 19A to 19C are enlarged cross-sectional views of a portion corresponding to the portion ENB of FIG. 4A, and FIGS. 19A to 19C are shown upside down as compared to the portion ENB of FIG. 4A.

Referring to FIG. 19A, after forming the extended opening BOPc shown in FIG. 16A, a spacer layer SPC that covers a surface of the first base substrate region BSUB1 exposed to the inner wall (e.g., boundary) of the extended opening BOPc is formed. For example, the spacer layer SPC may include nitride. FIG. 19A shows that the spacer layer SPC covers the surface of the first base substrate region BSUB1 exposed to the inner wall (e.g., boundary) of the extended opening BOPc and does not cover the surface of the preliminary insulation layer PILD, but the inventive concepts are not limited thereto. For example, the spacer layer SPC may be formed to cover both the surface of the first base substrate region BSUB1 exposed to the inner wall (e.g., boundary) of the extended opening BOPc and the surface of the preliminary insulation layer PILD.

Referring to FIG. 19B, a portion of the first base substrate region BSUB1 is removed from the bottom surface of the extended opening BOPc through isotropic etching using the preliminary insulation layer PILD and the spacer layer SPC as etching masks to form the extended opening POPc communicating with the extended opening BOPc. Because the extended opening POPc is formed through isotropic etching, the horizontal width of the extended opening POPc may be wider than the minimum horizontal width of the extended opening BOPc. The extended opening POPc may have a horizontal cross-section of a circular shape or a ring-like shape.

Referring to FIGS. 19B and 19C together, after removing the spacer layer SPC, the etch stop sacrificial film STB that fills the extended opening BOPc and the extended opening POPc is formed. Thereafter, subsequent operations are performed with reference to FIGS. 6G to 6N.

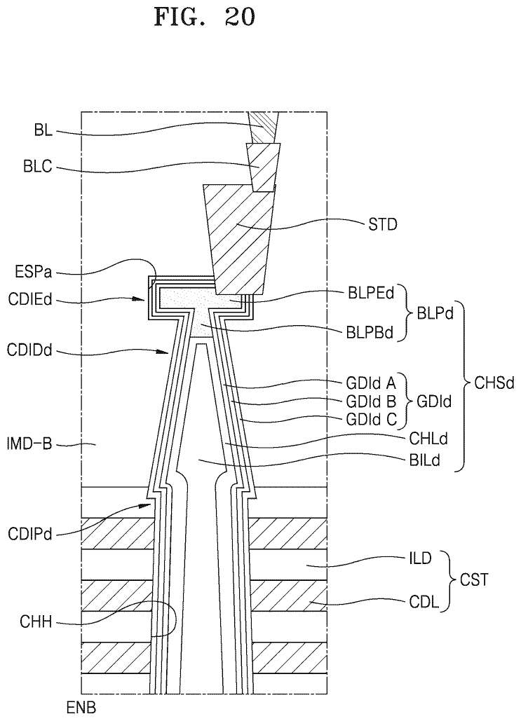

FIG. 20 is a cross-sectional view of a non-volatile memory device according to an example embodiment. In detail, FIG. 20 is an enlarged cross-sectional view of a portion corresponding to the portion ENB of FIG. 4A.

Referring to FIG. 20, the bit line pad BLPd and the stud STD may not be aligned in the vertical direction and may be misaligned. For example, the stud STD may be shifted from the bit line pad BLPd in a horizontal direction. When forming the stud STD connected to the bit line pad BLPd, even when misalignment occurs between the bit line pad BLPd and the stud STD, because the bit line pad BLPd includes the pad expansion BLPEd and the stud STD is connected to the pad expansion BLPEd having a relatively wide horizontal width, the connection reliability between the channel layer CHLd and the bit line BL may be improved.

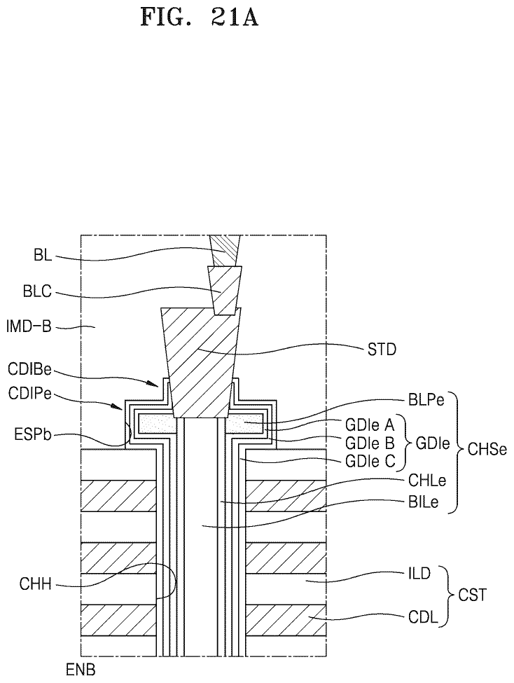

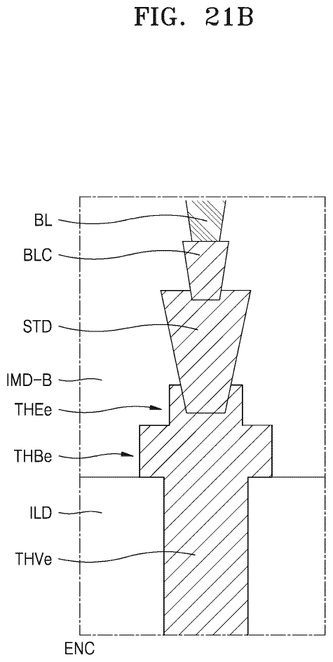

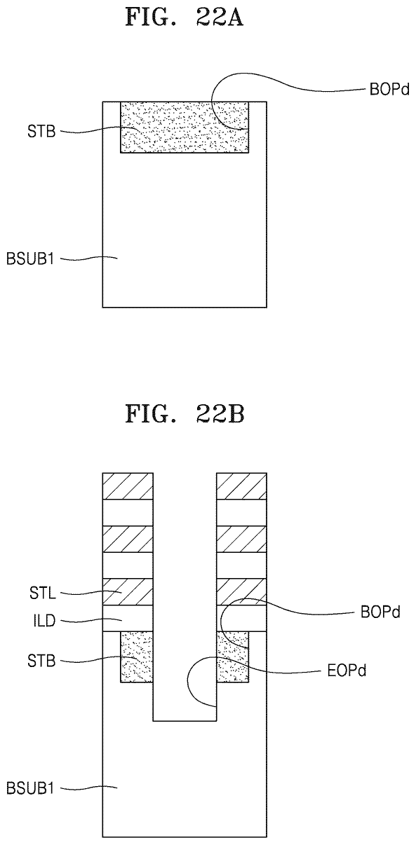

FIGS. 21A and 21B are cross-sectional views of a non-volatile memory device according to an example embodiment. In detail, FIG. 21A is an enlarged cross-sectional view of a portion corresponding to the portion ENB of FIG. 4A, and FIG. 21B is an enlarged cross-sectional view of a portion corresponding to the portion ENC of FIG. 4A.

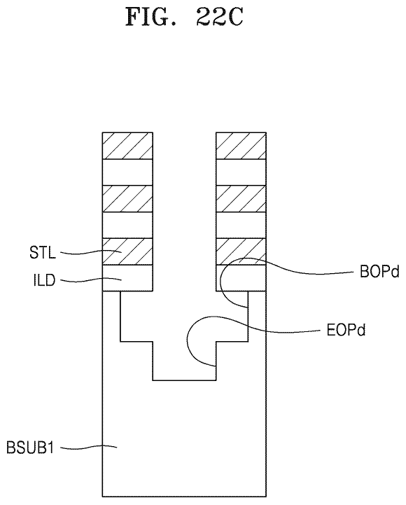

Referring to FIGS. 21A and 21B together, the channel hole CHH may include an expanded space ESPb corresponding to a base opening BOPd shown in FIGS. 22A to 22C and an extended space corresponding to an extended opening EOPd. The horizontal width of the expanded space ESPb may be greater than the horizontal widths of other portions of the channel hole CHH. The expanded space ESPb of the channel hole CHH may be located at the boundary between the cell stack CST and the bit line wiring insulation layer IMD-B. For example, the expanded space ESPb of the channel hole CHH may be disposed at a portion of the bit line wiring insulation layer IMD-B adjacent to the cell stack CST. The extended space of the channel hole CHH may extend from the expanded space ESPb toward the bit line BL.

A cell channel structure CHSe may include a gate insulation layer GDIe, a channel layer CHLe, a buried insulation layer BILe, and a bit line pad BLPe. The gate insulation layer GDIe may have a structure including a tunneling dielectric film GDIeA, a charge storage film GDIeB, and a blocking dielectric film GDIeC. The gate insulation layer GDIe may include a body portion of the gate insulation layer GDIe, an insulation protrusion CDIPe, and an insulation extension CDIBe. The insulation protrusion CDIPe may surround the bit line pad BLPe. The channel layer CHLe and the buried insulation layer BILe may each extend in a vertical direction along the channel hole CHH. The channel layer CHLe and the buried insulation layer BILe may each have a generally equal horizontal width in a vertical direction or may have a horizontal width that gradually decreases toward the bit line BL.

The bit line pad BLPe may fill a portion of the base opening BOPd as shown in FIGS. 22A to 22C. The bit line pad BLPe may have a horizontal cross-section of a ring-like shape or a rectangular ring-like shape. The bit line pad BLPe may surround the channel layer CHLe. The bit line pad BLPe may be positioned adjacent to an end of the channel layer CHLe.

The through via THVe may include a via protrusion THBe and a via extension THEe. The via protrusion THBe may have a horizontal width greater than that of the via extension THEe.

FIGS. 22A to 22C are cross-sectional views showing a method of manufacturing a non-volatile memory device, according to an example embodiment. In detail, FIGS. 22A to 22C are enlarged cross-sectional views of a portion corresponding to the portion ENB of FIG. 4A, and FIGS. 22A to 22C are shown upside down as compared to the portion ENB of FIG. 4A.

Referring to FIG. 22A, an upper portion of the first base substrate region BSUB1 is removed to form the base opening BOPd, and then the etch stop sacrificial film STB is formed to fill the base opening BOPd. The base opening BOPd may be formed to have a circular or rectangular horizontal cross-section.

Referring to FIG. 22B, after the plurality of interlayer insulation layers ILD and the plurality of sacrificial films STL are alternately formed on the first base substrate region BSUB1 and the etch stop sacrificial film STB, the extended opening EOPd that penetrates through the plurality of interlayer insulation layers ILD, the plurality of sacrificial films STL, and the etch stop sacrificial film STB and extends into the first base substrate region BSUB1 is formed.

Referring to FIGS. 22B and 22C together, after the etch stop sacrificial film STB is removed, subsequent operations are performed with reference to FIGS. 6J to 6N.

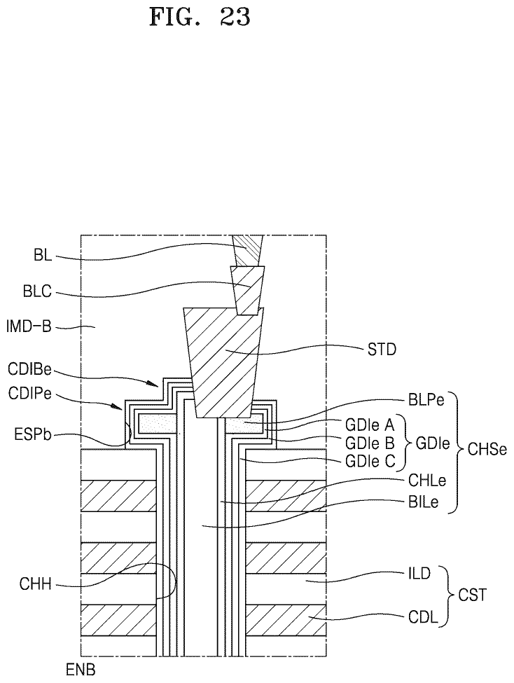

FIG. 23 is a cross-sectional view of a non-volatile memory device according to an example embodiment. In detail, FIG. 23 is an enlarged cross-sectional view of a portion corresponding to the portion ENB of FIG. 4A.

Referring to FIG. 23, the bit line pad BLPe and the stud STD may not be aligned in the vertical direction and may be misaligned. For example, the stud STD may be shifted from the bit line pad BLPe in a horizontal direction. When forming the stud STD connected to the bit line pad BLPe, even when a misalignment occurs between the bit line pad BLPe and the stud STD, the bit line pad BLPe has a relatively large horizontal width, and thus the connection reliability between the channel layer CHLe and the bit line BL may be improved.

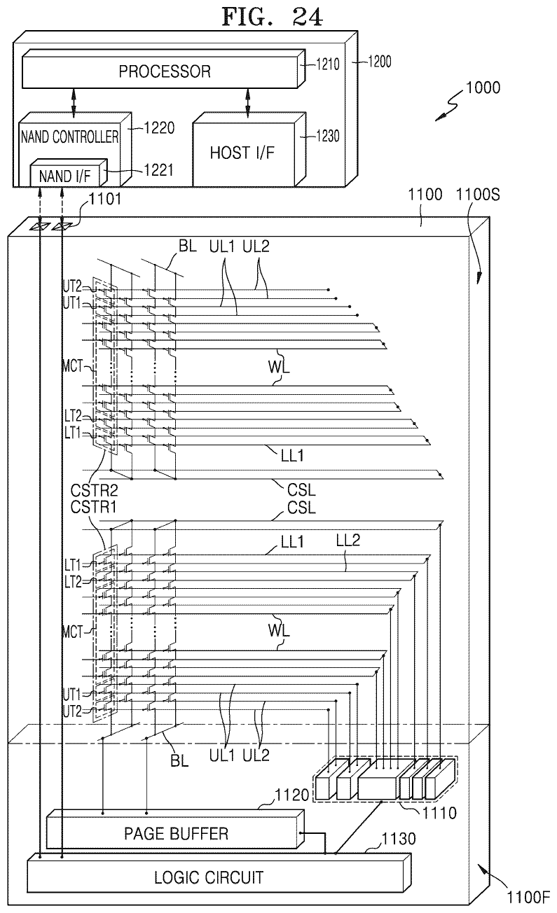

FIG. 24 is a schematic view of a memory system including a non-volatile memory device, according to an example embodiment.

Referring to FIG. 24, a memory system 1000 may include one or more memory devices 1100 and a memory controller 1200 electrically connected to the memory devices 1100. The memory system 1000 may be, for example, a solid state drive (SSD) device, a universal serial bus (USB), a computing system, a medical device, or a communication device including at least one memory device 1100.

A memory device 1100 may be a non-volatile memory device. For example, the memory device 1100 may be a NAND flash memory device including one of the non-volatile memory devices 1 described above with reference to FIGS. 1 to 23 or a combination thereof. The memory device 1100 may include a first structure 1100F and a second structure 1100S on the first structure 1100F. The first structure 1100F may correspond to the peripheral circuit structure PS shown in FIG. 2 or the peripheral circuit region Peri. shown in FIG. 4A. The peripheral circuit 30 shown in FIG. 1 may include a row decoder 1110, a page buffer 1120, and a logic circuit 1130. The plurality of peripheral circuit transistors P-TR shown in FIG. 4A may constitute the row decoder 1110, the page buffer 1120, and the logic circuit 1130.

The second structure 1100S may correspond to the cell array structure CS shown in FIGS. 2 and 3, or the stacked structure of the first bit line region BLR1, the first cell stack region Cell ST1, the first common source region CSL1, the lower cell bonding region BPU1, the upper cell bonding region BPU2, the second common source region CSL2, the second cell stack region Cell ST2, and the second bit line region BLR2 shown in FIG. 4A. The second structure 1100S may include a plurality of first memory cell strings CSTR1 and a plurality of second memory cell strings CSTR2. The plurality of first memory cell strings CSTR1 and the plurality of second memory cell strings CSTR2 are each positioned between the bit line BL and the common source line CSL and may be connected to the plurality of bit lines BL, the common source line CSL, and the plurality of word lines WL. The plurality of cell channel structures CHS and the plurality of gate electrodes CDL shown in FIG. 4A may form the plurality of first memory cell strings CSTR1 and the plurality of second memory cell strings CSTR2, respectively.

In the second structure 1100S, the plurality of first memory cell strings CSTR1 and the plurality of second memory cell strings CSTR2 may include ground select transistors LT1 and LT2 adjacent to the common source line CSL, string select transistors UT1 and UT2 adjacent to the bit line BL, and a plurality of memory cell transistors MCT arranged between the ground select transistors LT1 and LT2 and the string select transistors UT1 and UT2. The number of ground select transistors LT1 and LT2 and the number of string select transistors UT1 and UT2 may be variously changed according to example embodiments. One of the plurality of cell channel structures CHS and one of the plurality of gate electrodes CDL shown in FIG. 4a may constitute one of a plurality of transistors LT1, LT2, UT1, UT2, and MCT. The common source line CSL connected to the plurality of first memory cell strings CSTR1 and the common source line CSL connected to the plurality of second memory cell strings CSTR2 may be arranged between the plurality of first memory cell strings CSTR1 and the plurality of second memory cell strings CSTR2 to face each other.

The bit line BL connected to the plurality of first memory cell strings CSTR1 may be located on a side opposite to the plurality of second memory cell strings CSTR2 from the plurality of first memory cell strings CSTR1, and the bit line BL connected to the plurality of second memory cell strings CSTR2 may be located on a side opposite to the plurality of second memory cell strings CSTR2 from the plurality of first memory cell strings CSTR1.

According to some example embodiments, the first and second ground select lines LL1 and LL2 may be connected to gate electrodes of the ground select transistors LT1 and LT2 therebelow, respectively. A word line WL may be connected to a gate electrode of a memory cell transistor MCT. The first and second string select lines UL1 and UL2 may be connected to gate electrodes of the string select transistors UT1 and UT2, respectively.

The common source line CSL, the ground select lines LL1 and LL2, the word lines WL, and the first and second string select lines UL1 and UL2 may be connected to a row decoder 1110. The bit lines BL may be electrically connected to a page buffer 1120.

The memory device 1100 may communicate with the memory controller 1200 through external connection pads 1101 electrically connected to a logic circuit 1130. The external connection pads 1101 may be electrically connected to the logic circuit 1130. An external connection pad 1101 may correspond to the input/output pad PAD shown in FIG. 4A. The memory device 1100 may be electrically connected to the memory controller 1200 through a connection structure, such as a bonding wire connected to the external connection pad 1101.

The memory controller 1200 may include a processor 1210, a NAND controller 1220, and a host interface 1230. In some embodiments, the memory system 1000 may include a plurality of memory devices 1100. In this case, the memory controller 1200 may control the memory devices 1100.

The processor 1210 may control the overall operation of the memory system 1000 including the memory controller 1200. The processor 1210 may operate according to a certain firmware and may access the memory device 1100 by controlling the NAND controller 1220. The NAND controller 1220 may include a NAND interface 1221 that handles communication with the memory device 1100. Control commands for controlling the memory device 1100, data to be written to the memory cell transistors MCT of the memory device 1100, and data read from the memory cell transistors MCT of the memory device 1100 may be transmitted through the NAND interface 1221. The host interface 1230 may provide the function for communication between the memory system 1000 and an external host. When a control command is received from an external host through the host interface 1230, the processor 1210 may control the memory device 1100 in response to the control command.

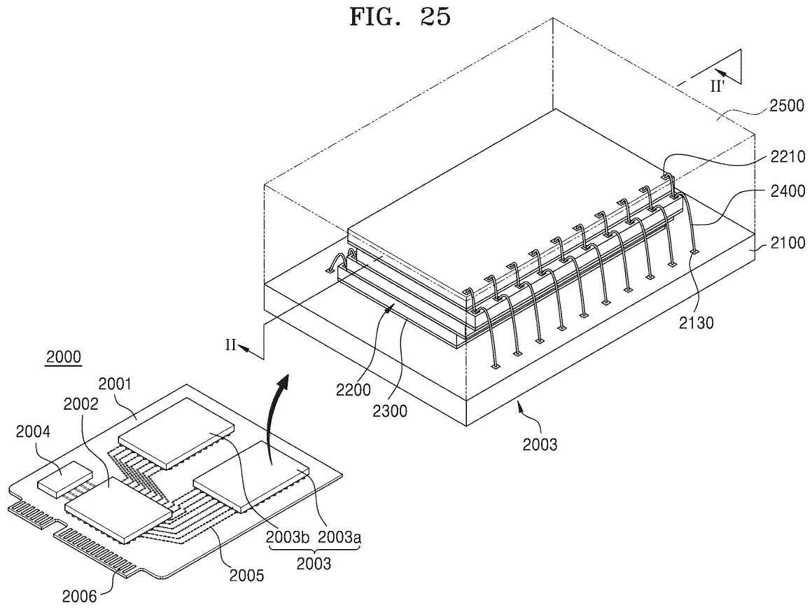

FIG. 25 is a schematic perspective view of a memory system including a non-volatile memory device, according to an example embodiment.

Referring to FIG. 25, a memory system 2000 according to an example embodiment may include a main substrate 2001, a memory controller 2002 mounted on the main substrate 2001, one or more semiconductor packages 2003, and a DRAM 2004. The semiconductor package 2003 and the DRAM 2004 may be connected to the memory controller 2002 by a plurality of wiring patterns 2005 formed on the main substrate 2001.

The main substrate 2001 may include a connector 2006 including a plurality of pins configured to be coupled to an external host. The number and arrangement of the pins of the connector 2006 may vary according to a communication interface between the memory system 2000 and the external host. In example embodiments, the memory system 2000 may communicate with an external host according to any one of interfaces including a universal serial bus (USB), peripheral component interconnect express (PCI-Express), serial advanced technology attachment (SATA), M-Phy for universal flash storage (UFS), etc. In some example embodiments, the memory system 2000 may operate by power supplied from an external host through the connector 2006. The memory system 2000 may further include a power management integrated circuit (PMIC) that distributes power supplied from the external host to the memory controller 2002 and the semiconductor package 2003.

The memory controller 2002 may write data to or read data from the semiconductor package 2003 and may improve the operating speed of the memory system 2000.

The DRAM 2004 may be a buffer memory for mitigating the speed difference between the semiconductor package 2003, which is a data storage space, and an external host. The DRAM 2004 included in the memory system 2000 may also operate as a type of cache memory and may provide a space for temporarily storing data in a control operation for the semiconductor package 2003. When the DRAM 2004 is included in the memory system 2000, the memory controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. The first and second semiconductor packages 2003a and 2003b may each be a semiconductor package including a plurality of semiconductor chips 2200. The first and second semiconductor packages 2003a and 2003b may each include a package substrate 2100, the semiconductor chips 2200 on the package substrate 2100, an adhesive layer 2300 disposed on the bottom surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The plurality of semiconductor chips 2200 may each include at least one of the non-volatile memory devices 10 described above with reference to FIGS. 1 to 23. The semiconductor chips 2200 may each include input/output pads 2210. The input/output pad 2210 may correspond to the input/output pad PAD shown in FIG. 4A. The package substrate 2100 may be a printed circuit board including a plurality of package upper pads 2130.

In some example embodiments, the connection structure 2400 may be a bonding wire electrically connecting the input/output pad 2210 and the package upper pad 2130. Therefore, in the first and second semiconductor packages 2003a and 2003b, the semiconductor chips 2200 may be electrically connected to one another through bonding wires and may be electrically connected to the package upper pads 2130 of the package substrate 2100.

According to some example embodiments, the memory controller 2002 and the semiconductor chips 2200 may be included in one package. According to some example embodiments, the memory controller 2002 and the semiconductor chips 2200 may be mounted on a separate interposer substrate different from the main substrate 2001 and the memory controller 2002 and the semiconductor chips 2200 may be connected to each other through wires formed on the interposer substrate.

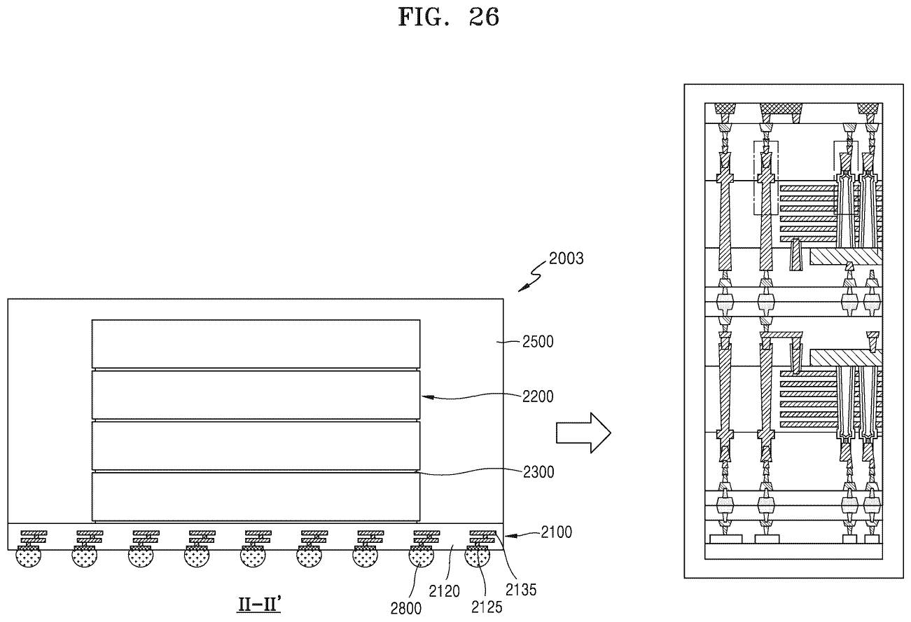

FIG. 26 is a schematic cross-sectional view of a semiconductor package according to an example embodiment.

Referring to FIG. 26, in a semiconductor package 2003, the package substrate 2100 may be a printed circuit board. The package substrate 2100 may include a package substrate body 2120, a plurality of package upper pads 2130 (refer to FIG. 25) arranged on the top surface of the package substrate body 2120, a plurality of package lower pads 2125 arranged or exposed on the bottom surface of the package substrate body 2120, and a plurality of internal wires 2135 electrically connecting the package upper pads 2130 (refer to FIG. 25) and the package lower pads 2125 inside the package substrate body 2120. As shown in FIG. 25, the plurality of package upper pads 2130 may be electrically connected to a plurality of connection structures 2400. The package lower pads 2125 may be connected to the wiring patterns 2005 on the main substrate 2001 of the memory system 2000 shown in FIG. 25 through a plurality of conductive bumps 2800. The plurality of semiconductor chips 2200 may each include at least one of the non-volatile memory devices 1 described above with reference to FIGS. 1 to 23.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. A non-volatile memory device comprising:
a peripheral circuit structure comprising a peripheral circuit, the peripheral circuit including a plurality of peripheral circuit transistors; and
a cell array structure on the peripheral circuit structure, the cell array structure electrically connected to the peripheral circuit structure, the cell array structure comprising a common source line layer, a bit line, a bit line wiring insulation layer surrounding the bit line, a cell stack being between the common source line layer and the bit line in a vertical direction, the cell stack including a plurality of gate electrodes and a plurality of interlayer insulation layers alternating in the vertical direction, and a plurality of channel structures extending through the cell stack into the bit line wiring insulation layer,
wherein each of the plurality of channel structures comprises a channel layer, a bit line pad, and a gate insulation layer, the channel layer electrically connected to the common source line layer, the bit line pad electrically connecting the channel layer to the bit line and being adjacent to one end of the channel layer facing the bit line, and the gate insulation layer covering the channel layer and the bit line pad, and
the gate insulation layer comprises an insulation protrusion, the insulation protrusion being at a boundary between the bit line wiring insulation layer and the cell stack, the insulation protrusion protruding in a horizontal direction further than a portion of the gate insulation layer penetrating through the cell stack.

2. The non-volatile memory device of claim 1, wherein
the cell array structure further comprises a stud, the stud being in contact with the bit line pad and electrically connecting the bit line to the bit line pad, and
the gate insulation layer is in contact with at least a portion of a side surface of the stud.

3. The non-volatile memory device of claim 2, wherein the bit line pad has a T-shaped vertical cross-section, the T-shaped vertical cross-section comprising a pad extension and a pad expansion, the pad extension connected to the channel layer, the pad expansion connected to the stud and having a horizontal width wider than a horizontal width of the pad extension.

4. The non-volatile memory device of claim 2, wherein the bit line pad has a cross-shaped vertical cross-section, the cross-shaped vertical cross-section comprising a first pad extension, a second pad extension, and a pad expansion, the first pad extension connected to the channel layer, the second pad extension connected to the stud, and the pad expansion having a horizontal width wider than a horizontal width of each of the first pad extension and the second pad extension, the pad expansion being between the first pad extension and the second pad extension.

5. The non-volatile memory device of claim 2, wherein the bit line pad is in contact with a portion of a bottom surface and a portion of the side surface of the stud.

6. The non-volatile memory device of claim 1, wherein, in each of the plurality of channel structures, a portion extending from one end of the cell stack facing the bit line toward the bit line has a tapered shape of which a horizontal width decreases toward the bit line.

7. The non-volatile memory device of claim 1, wherein the channel layer comprises a channel protrusion, the channel protrusion protruding in a horizontal direction from a portion of the channel layer penetrating through the cell stack, the channel protrusion corresponding to the insulation protrusion.

8. The non-volatile memory device of claim 7, wherein
each of the plurality of channel structures further comprises a buried insulation layer, the buried insulation layer filling a space defined by the channel layer, and
the buried insulation layer comprises a buried protrusion, the buried protrusion protruding in a horizontal direction from a portion of the buried insulation layer penetrating through the cell stack, the buried protrusion corresponding to the insulation protrusion and the channel protrusion.

9. The non-volatile memory device of claim 1, wherein the insulation protrusion of the gate insulation layer is within a portion of the bit line wiring insulation layer adjacent to the cell stack.

10. The non-volatile memory device of claim 1, wherein
the cell array structure comprises a first cell array structure and a second cell array structure on the first cell array structure, each of the first cell array structure and the second cell array structure comprising the common source line layer, the bit line, the bit line wiring insulation layer, the cell stack, and the plurality of channel structures, and
the common source line layer of the first cell array structure and the common source line layer of the second cell array structure are between the cell stack of the first cell array structure and the cell stack of the second cell array structure.

11. A non-volatile memory device comprising:
a peripheral circuit structure comprising a peripheral circuit, the peripheral circuit including a plurality of peripheral circuit transistors;
a first cell array structure on the peripheral circuit structure, the first cell array structure electrically connected to the peripheral circuit structure, the first cell array structure comprising a first bit line, a first bit line wiring insulation layer surrounding the first bit line, a first common source line layer, a first cell stack being between the first bit line and the first common source line layer in a vertical direction, the first cell stack including a plurality of first gate electrodes and a plurality of first interlayer insulation layers alternating in the vertical direction, and a plurality of first channel structures extending through the first cell stack into the first bit line wiring insulation layer; and
a second cell array structure on the first cell array structure, the second cell array structure electrically connected to the first cell array structure, the second cell array structure comprising a second common source line layer, a second bit line, a second bit line wiring insulation layer surrounding the second bit line, a second cell stack being between the second common source line layer and the second bit line in the vertical direction, the second cell stack including a plurality of second gate electrodes and a plurality of second interlayer insulation layers alternating in the vertical direction, and a plurality of second channel structures extending through the second cell stack into the second bit line wiring insulation layer, the first common source line layer and the second common source line layer being between the first cell stack and the second cell stack,
each of the plurality of first channel structures comprises a first channel layer, a first bit line pad, and a first gate insulation layer, the first channel layer electrically connected to the first common source line layer, the first bit line pad electrically connecting the first channel layer and the first bit line, the first bit line pad being adjacent to one end of the first channel layer facing the first bit line, and the first gate insulation layer covering the first channel layer and the first bit line pad,
each of the plurality of second channel structures comprises a second channel layer, a second bit line pad, and a second gate insulation layer, the second channel layer electrically connected to the second common source line layer, the second bit line pad electrically connecting the second channel layer and the second bit line, the second bit line pad being adjacent to one end of the second channel layer facing the second bit line, and the second gate insulation layer covering the second channel layer and the second bit line pad,
the first gate insulation layer comprises a first insulation protrusion, the first insulation protrusion being at a boundary between the first bit line wiring insulation layer and the first cell stack, the first insulation protrusion protruding in a horizontal direction further than a portion of the first gate insulation layer penetrating through the first cell stack, and
the second gate insulation layer comprises a second insulation protrusion, the second insulating protrusion being at a boundary between the second bit line wiring insulation layer and the second cell stack, the second insulation protrusion protruding in the horizontal direction further than a portion of the second gate insulation layer penetrating through the second cell stack.

12. The non-volatile memory device of claim 11, wherein
the first cell array structure further comprises a first stud, the first stud being in contact with the first bit line pad and electrically connecting the first bit line and the first bit line pad,
the second cell array structure further comprises a second stud, the second stud being in contact with the second bit line pad and electrically connecting the second bit line and the second bit line pad,
the first gate insulation layer is in contact with at least a portion of a side surface of the first stud, and
the second gate insulation layer is in contact with at least a portion of a side surface of the second stud.

13. The non-volatile memory device of claim 12, wherein
the first bit line pad is in contact with at least a portion of a bottom surface and at least a portion of the side surface of the first stud, and
the second bit line pad is in contact with at least a portion of a bottom surface and at least a portion of the side surface of the second stud.

14. The non-volatile memory device of claim 12, wherein
the first bit line pad comprises a first pad extension and a first pad expansion, the first pad extension connected to the first channel layer, the first pad expansion connected to the first stud, the first pad expansion having a horizontal width wider than a horizontal width of the first pad extension, and
the second bit line pad comprises a second pad extension and a second pad expansion, the second pad extension connected to the second channel layer, the second pad expansion connected to the second stud, the second pad expansion having a horizontal width wider than a horizontal width of the second pad extension.

15. The non-volatile memory device of claim 12, wherein
the first bit line pad comprises a first pad extension, a second pad extension, and a first pad expansion, the first pad extension connected to the first channel layer, the second pad extension connected to the first stud, the first pad expansion having a horizontal width wider than a horizontal width of the first pad extension and the second pad extension, the first pad expansion being between the first pad extension and the second pad extension, and
the second bit line pad comprises a third pad extension, a fourth pad extension, and a second pad expansion, the third pad extension connected to the second channel layer, the fourth pad extension connected to the second stud, the second pad expansion having a horizontal width wider than a horizontal width of the third pad extension and the fourth pad extension, the second pad expansion being between the third pad extension and the fourth pad extension.

16. The non-volatile memory device of claim 11, wherein
a portion of each of the plurality of first channel structures extending from one end of the first cell stack facing the first bit line toward the first bit line has a tapered shape of which a horizontal width decreases toward the first bit line, and
a portion of each of the plurality of second channel structures extending from one end of the second cell stack facing the second bit line toward the second bit line have a tapered shape of which a horizontal width decreases toward the second bit line.

17. The non-volatile memory device of claim 11, wherein
the first channel layer comprise a first channel protrusion corresponding to the first insulation protrusion, and
the second channel layer comprise a second channel protrusion corresponding to the second insulation protrusion.

18. A memory system comprising:
a non-volatile memory device comprising
a peripheral circuit structure, the peripheral circuit structure comprising a peripheral circuit, the peripheral circuit including a plurality of peripheral circuit transistors,
a first cell array structure on the peripheral circuit structure,
a second cell array structure on the first cell array structure, and
an input/output pad disposed on the second cell array structure, wherein each of the first cell array structure and the second cell array structure comprises a common source line layer, a bit line, a bit line wiring insulation layer surrounding the bit line, a cell stack being between the common source line layer and the bit line in a vertical direction, the cell stack including a plurality of gate electrodes and a plurality of interlayer insulation layers alternating in the vertical direction, and a plurality of channel structures extending through the cell stack into the bit line wiring insulation layer; and
a memory controller electrically connected to the non-volatile memory device through the input/output pad and configured to control the non-volatile memory device,
wherein the common source line layer of the first cell array structure and the common source line layer of the second cell array structure are arranged between the cell stack of the first cell array structure and the cell stack of the second cell array structure,
each of the plurality of channel structures included in each of the first cell array structure and the second cell array structure comprises a channel layer, a bit line pad, and a gate insulation layer, the channel layer electrically connected to the common source line layer, the bit line pad electrically connecting the channel layer to the bit line, the bit line pad being adjacent to one end of the channel layer facing the bit line, and the gate insulation layer covering the channel layer and the bit line pad, and
the gate insulation layer included in each of the first cell array structure and the second cell array structure comprises an insulation protrusion, the insulation protrusion being at a boundary between the bit line wiring insulation layer and the cell stack, the insulation protrusion protruding in a horizontal direction further than a portion of the gate insulation layer penetrating through the cell stack.

19. The memory system of claim 18, wherein each of the first cell array structure and the second cell array structure further comprises a stud that electrically connects the bit line and the bit line pad, the stud being in contact with the bit line pad, and at least a portion of a side surface of the stud being in contact with the gate insulation layer.

20. The memory system of claim 18, wherein the channel layer included in each of the first cell array structure and the second cell array structure comprises a channel protrusion, the channel protrusion protruding in a horizontal direction further than a portion of the channel layer penetrating through the cell stack, the channel protrusion corresponding to the insulation protrusion.
